(19) United States
(12) Patent Application Publication
(10) Pub. No.: US 2025/0115995 A1
(43) Pub. Date: Apr. 10, 2025

(54) MIXING BLOCKS FOR FLUID SYSTEMS, FIXTURES AND FIXTURE ARRANGEMENTS INCLUDING MIXING BLOCKS, AND METHODS OF MAKING MIXING BLOCKS FOR FLUID SYSTEMS

(71) Applicant: ASM IP Holding B.V., Almere (NL)

(72) Inventors: Iordan Iordanov, Tempe, AZ (US); Jeffrey Hintz, Phoenix, AZ (US); Shreyas Parameshwaran, Laveen Village, AZ (US); Dinkar Nandwana, Chandler, AZ (US); Lee Donohue, Avon, CT (US); David Groechel, Scottsdale, AZ (US)

(21) Appl. No.: 18/904,480

(22) Filed: Oct. 2, 2024

Related U.S. Application Data
(60) Provisional application No. 63/542,912, filed on Oct. 6, 2023.

(51) Int. Cl. C23C 16/455; C23C 16/44; C23C 16/458

(52) U.S. Cl. CPC C23C 16/45512; C23C 16/4408; C23C 16/45544; C23C 16/4583

(57) ABSTRACT

A fixture includes a first end plate, a threaded member, a second end plate, and a compression member. The first end plate has a first end plate recess. The threaded member is fixed in the first end plate in extends in a direction opposite the first end plate recess. The second end plate has a second end plate recess facing the first end plate recess and is slidably received on the threaded member. The compression member is arranged on a side of the second end plate opposite the first end plate and is threadedly seated on a male threaded segment of the threaded member to reverse flow a purge fluid through a mixing block compressively fixed between the first end plate and the second end plate. Fixture arrangements, methods of making mixing blocks, mixing blocks, and semiconductor processing systems including mixing blocks are also described.

### CROSS-REFERENCE TO RELATED APPLICATIONS

This application claims priority to and the benefits of U.S. Provisional Patent Application Ser. No. 63/542,912, filed Oct. 6, 2023, titled MIXING BLOCKS FOR FLUID SYSTEMS, FIXTURES AND FIXTURE ARRANGEMENTS INCLUDING MIXING BLOCKS, AND METHODS OF MAKING MIXING BLOCKS FOR FLUID SYSTEMS, the contents of which is hereby incorporated by reference in its entirety.

### FIELD OF INVENTION

The present disclosure generally relates to fluid systems, and more particularly, to fluids systems employing mixing blocks to intermix fluids in fluid systems.

### BACKGROUND OF THE DISCLOSURE

Mixers are commonly employed in fluid systems to intermix fluids, such material precursors and reactants in semiconductor processing systems. Mixing may be accomplished in such mixers by introducing fluids into interior passageways defined within the mixer, flowing the fluids to a mixing passageway, and therefrom flowing the intermixed fluids to an outlet such that the fluids intermix with one another prior to issue from the mixer outlet. Such mixers may be formed using a subtractive manufacturing technique, such as by drilling and reaming. Such mixers may also be formed using additive technique, such as casting or a laser sintering technique like powder bed fusion. Once the passageways within the mixer are formed the mixer typically undergoes a post-fabrication cleaning process, such as to clear chips and cuttings associated with subtractive techniques as well as flash or residual powder associated with additive techniques. The mixer may also undergo a post-fabrication cleaning process, for example to remove accumulated material accretions associated with fluid traversing the mixer during use in a fluid system.

In some mixers access to interior passages such as the inlet channel and/or the mixing channel may be limited due to inability to visually inspect internal surfaces within the mixer bounding the passage. For example, inlet channels may be accessible only through the inlet to the inlet channel and the outlet of the mixing channel, and the interior surfaces of the inlet channel may not be visible to access whether chips and cuttings remaining within the inlet channel have been fully cleared during a post-fabrication cleaning process. For similar reasons residual accreted material accumulations on interior surfaces the inlet channel may not be visible to access the efficacy of an effort to clean the mixer subsequent to employment of the mixer in a fluid system. As a consequence, new and newly cleaned mixers may present contamination risk to the fluid systems employing the mixers.

Various countermeasures exist to limit the risk of fluid system contamination due to the installation of a newly fabricated or cleaned mixer in a fluid system. For example, the mixer may be rinsed after cleaning to mobilize and remove chips and cuttings that may reside within the mixer following fabrication. Interior passages of the mixer may be visually inspected following cleaning, such as inserting a borescope into an interior passage of the mixer. And the mixer may undergo qualification within the fluid system employing the mixer subsequent to installation to assess whether the mixer is a source of contamination to the system. While generally adequate for their intended purpose, chips and cuttings as well as residual material accretions may resist removal using rinsing techniques. Visual inspection of mixers may increase the cost of mixer manufacture and cleaning due to the complexity and specialized training associated with visual inspection devices like borescopes. And post installation qualification testing of new-built or newly cleaned mixers limits the availability of the fluid system employing the mixer and increases cost of ownership of the fluid system.

Such methods and systems have generally been considered suitable for their intended purpose. However, there remains a need in the art for improved methods of making mixers, fixtures and fixture arrangements for making mixers, and fluid systems and semiconductor processing systems including mixers. The present disclosure provides a solution to this need.

### SUMMARY OF THE DISCLOSURE

A fixture is provided. The fixture includes a first end plate, a threaded member, a second end plate, and a compression member. The first end plate has a first end plate recess. The threaded member is fixed in the first end plate in extends in a direction opposite the first end plate recess. The second end plate has a second end plate recess facing the first end plate recess and is slidably received on the threaded member. The compression member is arranged on a side of the second end plate opposite the first end plate and is threadedly seated on a male threaded segment of the threaded member to reverse flow a purge fluid through a mixing block compressively fixed between the first end plate and the second end plate.

In addition to one or more of the features described above, or as an alternative, further examples of the fixture may include that the first end plate is formed from a polymeric material. The second end plate may also be formed from a (or the) polymeric material.

In addition to one or more of the features described above, or as an alternative, further examples of the fixture may include that the threaded member is formed from a polymeric material. The compression member may be formed from a metallic material.

In addition to one or more of the features described above, or as an alternative, further examples of the fixture may include a first seal member and a second seal member. The first seal member may be arranged in the first end plate recess. The second seal member may be arranged in the second end pate recess. The first seal member may fluidly couple the first end plate to the second seal member and the second seal member may fluidly couple the second end plate to the first seal member.

In addition to one or more of the features described above, or as an alternative, further examples of the fixture may include that the first seal member is loose fit in the first end plate recess defined by the first end plate and that the second seal member may be loose fit in the second end plate recess defined by the second end plate.

In addition to one or more of the features described above, or as an alternative, further examples of the fixture may include that the first seal member is captive within a first end plate recess surface of the first end plate, and that the second seal member is captive within the second end plate recess surface of the second end plate.

In addition to one or more of the features described above, or as an alternative, further examples of the fixture may include a purge fluid fitting and a first purge fluid source. The purge fluid fitting may be seated in the first end plate and fluidly coupled by the first end plate to the second end plate recess. The first purge fluid source may include a first purge fluid, for example a gaseous purge fluid or a liquid purge fluid at standard atmospheric conditions and may be coupled to the purge fluid fitting and fluidly coupled therethrough to the second end plate recess.

In addition to one or more of the features described above, or as an alternative, further examples of the fixture may include that the first purge fluid is a gaseous purge fluid.

In addition to one or more of the features described above, or as an alternative, further examples of the fixture may include that the first purge fluid one or more includes oil-free air or clean dry air.

In addition to one or more of the features described above, or as an alternative, further examples of the fixture may include a plug. The plug may be seated in the second end plate. The plug may fluidly separate the second end plate recess from an external environment outside the fixture.

In addition to one or more of the features described above, or as an alternative, further examples of the fixture may include a purge fluid fitting and a second purge fluid fitting. The purge fluid fitting may be seated in the second end plate and fluidly coupled by the second end plate to the first end plate recess. The second purge fluid source may include a second purge fluid, e.g., a gaseous or a liquid purge fluid at standard atmospheric conditions and may be coupled to the purge fluid fitting and fluidly coupled therethrough to the first end plate recess.

In addition to one or more of the features described above, or as an alternative, further examples of the fixture may include that the second purge fluid is a liquid purge fluid.

In addition to one or more of the features described above, or as an alternative, further examples of the fixture may include that the second purge fluid may include ultra-pure water or deionized water.

A fixture arrangement is provided. The fixture arrangement includes a fixture as described above, a mixing block, a plug, and purge fluid fitting. The mixing block includes a mixing block body and is compressively fixed between the first end plate and the second end plate of the fixture. The mixing block body has a first end face with a cul-de-sac port received in the first recess of the first end plate; a second end face with an outlet port longitudinally opposite the first end face received in the second recess of the second end plate, the outlet port fluidly coupled to the cul-de-sac port defined of the first end face by a mixing channel extending through the mixing block body; a first lateral face with a first inlet port separating the second end face from the first end face, the first inlet port fluidly coupled to the mixing channel at a confluence; and a second lateral face with a second inlet port separating the second end face from the first end face, the second inlet port fluidly coupled to the mixing channel at the confluence. The purge fluid fitting is seated in one of the first end plate and the second end plate to communicate a purge fluid to the mixing channel. The plug is seated in the other of the first end plate and the second end plate to force the purge fluid through the first and second inlet port of the mixing block body.

In addition to one or more of the features described above, or as an alternative, further examples of the fixture arrangement may include a first purge fluid source and a first seal member. The first purge fluid source may include a gaseous purge fluid coupled to the purge fluid fitting. The first seal member may be arranged within the first recess and fluidly couple the first purge fluid source to the cul-de-sac port of the mixing block body. The first inlet port and the second inlet port may fluidly couple the first purge fluid source through the cul-de-sac port to an external environment bounding the mixing block body.

In addition to one or more of the features described above, or as an alternative, further examples of the fixture arrangement may include a second purge fluid source and a second seal member. The second purge fluid source may include a liquid purge fluid coupled to the purge fluid fitting. The second seal member may be arranged within the second recess and fluidly couple the second purge fluid source to the outlet port of the mixing block body. The first inlet port and the second inlet port may fluidly couple the second purge fluid source through the cul-de-sac port to an external environment bounding the mixing block body.

In addition to one or more of the features described above, or as an alternative, further examples of the fixture arrangement may include that the purge fluid fitting may be seated in the first end plate, that the first end face of the mixing block body may be received in the first end plate recess of the first end plate, and that the first end plate recess may separate the purge fluid fitting from the first end face of the mixing block body.

In addition to one or more of the features described above, or as an alternative, further examples of the fixture arrangement may include that the purge fluid fitting may be seated in the second end plate, that the second end face of the mixing block body may be received in the second end plate recess of the second end plate, and that the second end plate recess may separate the purge fluid fitting from the second end face of the mixing block body.

In addition to one or more of the features described above, or as an alternative, further examples of the fixture arrangement may include that the mixing block is formed from a mixing block material having a hardness and that the first end plate is formed from a first end plate material having hardness that is less than the hardness of the mixing block material. The second end plate may be formed from a second end plate material that has a hardness that is less than the hardness of the mixing block material. The threaded member may be formed from a threaded member material having a hardness that is less than (or substantially equal to) the hardness of the mixing block material.

A method of making a mixing block is provided. The method includes, at a mixing block as described above, compressively fixing the mixing block body in a fixture between a first end plate having a first end plate recess and a second end plate having a second recess by fixing a threaded member in the first end plate such that the threaded member extends in a direction opposite the first end plate recess, slidably receiving the threaded member in the second end plate such that the second end plate recess faces the first end plate recess, and arranging a compression member on a side of the second end plate opposite the first end plate and threadedly seating the compression member on the threaded member. A purge fluid fitting is seated in one of the first end plate and the second end plate, a plug is seated in the other of the first end plate and the second end plate, and a purge fluid introduced into the mixing channel through the purge fluid fitting and one of the first recess and the second recess. It is contemplated that the plug member impound a portion of the purge fluid within one of the first end plate recess and the second end plate recess, that the purge fluid be reverse flowed through the mixing block body by communicating the purge fluid from the mixing channel to the first inlet port and the second inlet from a confluence defined along the mixing channel, the confluence coupled to the first inlet port by a first source channel and to the second inlet port by a second source channel, that the purge fluid issue from the first inlet port and the second inlet port into an environment bounding the mixing block body.

In addition to one or more of the features described above, or as an alternative, further examples of the method may include that the purge fluid is a gaseous purge fluid, the one of the first end plate and the second end plate is the first end plate of the fixture, and that the method further includes removing the plug from the second end plate and the purge fluid fitting from the first end plate, fixing the plug in the first end plate and the purge fluid fitting in the second end plate, introducing a liquid purge fluid into the mixing channel through the purge fluid fitting and the second end plate recess, the plug member impounding a portion of the liquid purge fluid in the first end plate recess, reverse flowing the liquid purge fluid through the mixing block body by communicating the liquid purge fluid from the mixing channel to the first inlet port and the second inlet from a confluence defined along the mixing channel, and issuing the liquid purge fluid from the first inlet port and the second inlet port into an environment bound the mixing block body.

A mixing block is provided. The mixing block is made using the above-described method of making a mixing block.

A semiconductor processing system is provided. The semiconductor processing system includes a first process fluid source and a second process fluid source; a mixing block made using the method of making a mixing block as described above, the first process fluid source connected to the first inlet port of the mixing block body and the second process fluid source connected to the second inlet port of the mixing block body; a chamber arrangement coupled to the outlet port of the mixing block body and therethrough to the first process fluid source and the second process fluid source; and a substrate support and a distribution plate arranged within the chamber arrangement. The distribution plate fluidly couples the substrate support to the mixing block body to deposit a material layer onto a substrate or remove material from the substrate using a first fluid from the first fluid source and a second fluid from the second fluid source intermixed by the mixing block body.

In addition to one or more of the features described above, or as an alternative, further examples of the semiconductor processing system may include one or more of the first process fluid source and the second process fluid source includes a material layer precursor for depositing a material layer using an atomic layer deposition technique.

In addition to one or more of the features described above, or as an alternative, further examples the semiconductor processing system may include that one or more of the first process fluid source and the second process fluid source includes a material layer precursor for depositing a material layer using a chemical vapor deposition technique.

In addition to one or more of the features described above, or as an alternative, further examples the semiconductor processing system may include that one or more of the first process fluid source and the second process fluid source includes an etchant or an etchant precursor for removing material from the substrate using a dry etch technique.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a fluid system including a mixing block and a related fixture in accordance with the present disclosure, showing the mixing block being installed in the fluid system after purging in a fixture arrangement including the fixture;

FIG. 2 is cross-sectional side view of the mixing block of FIG. 1 according to an example of the present disclosure, showing the mixing block fluidly coupling fluid sources to a chamber arrangement in a semiconductor processing system;

FIG. 3 is a perspective view of the fixture arrangement of FIG. 1 according to an example of the present disclosure, showing mixing block compressively seated within the fixture for purging using a purge fluid;

FIG. 4 is cross-sectional view of the fixture arrangement of FIG. 1 according to an example of the present disclosure, showing a purge fluid being reverse flowed through the mixing block in relation to normal flow of fluid through the mixing block;

FIG. 5 is an exploded view of the fixture arrangement of FIG. 1 according to an example of the present disclosure, showing a first end plate and a second end plate exploded away from the mixing block;

FIGS. 6-11 are plan and cross-sectional side views of the first and second end plates of the fixture of FIG. 1 according to examples of the present disclosure, showing recesses defined within the end plates and sealing members arranged within the recesses according to examples of the present disclosure;

FIG. 12 is a side view of a threaded member included in the fixture of FIG. 1 according to an example of the present disclosure, showing a male threaded segment with male threads defined between a tip and a head of the threaded member;

FIG. 13 is a cross-sectional side view of a compression member included in the fixture of FIG. 1 according to an example of the present disclosure, showing female threads corresponding to male threads of the threaded member defined within the compression member;

FIG. 14 side view of a plug included in the fixture of FIG. 1 according to an example of the present disclosure, showing a male threaded segment having male threads corresponding to female threads defined within plug/purge fluid fitting apertures defined within the end plates of the fixture to impound purge fluid within the fixture arrangement;

FIG. 15 side view of a purge fluid fitting included in the fixture of FIG. 1 according to an example of the present disclosure, showing a male threaded segment having male threads corresponding to female threads defined within the plug/purge fluid fitting apertures defined within the end plates of the fixture to introduce purge fluid int the fixture arrangement;

FIGS. 16 and 17 are a block diagram of a method of making a mixing block according to an illustrative and non-limiting example, showing operations of the method; and

FIG. 18 is a block diagram of operations of the method of FIGS. 16 and 17 according to an example, showing operations for reversing direction of purge fluid introduction into the mixing block while retaining reverse flow of the purge through the mixing block.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

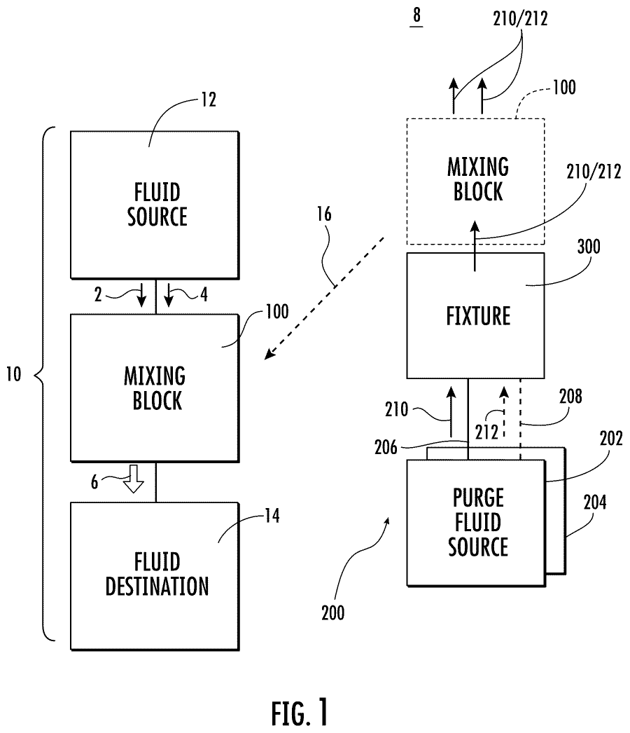

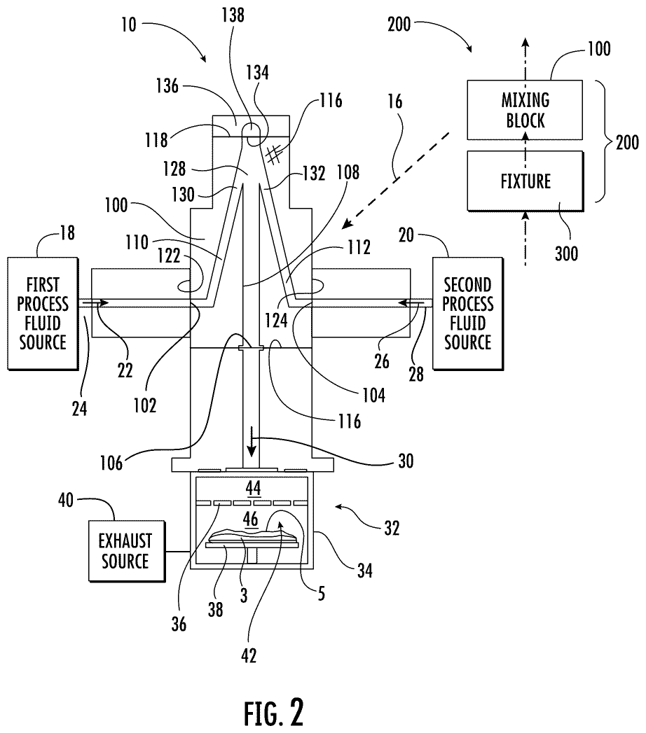

Reference will now be made to the drawings wherein like reference numerals identify similar structural features or aspects of the subject disclosure. For purposes of explanation and illustration, and not limitation, a partial view of an example of a fixture for a mixing block in accordance with the present disclosure is shown in FIG. 1 and is designated generally by reference character 300. Other examples of fixtures, fixture arrangements including fixtures and mixing blocks, and methods of making mixing blocks in accordance with the present disclosure, or aspects thereof, are provided in FIGS. 2-18, as will be described. The fixtures and fixture arrangements of the present disclosure may be used in methods to make and clean mixing blocks employed in fluid systems to intermix fluids, such as mixing blocks employed to provide precursors to reactors semiconductor processing systems used to deposit material layers onto substrates using atomic layer deposition (ALD) or chemical vapor deposition (CVD) techniques, though the present disclosure is not limited any particular type of precursor supply system or to semiconductor processing systems in general.

Referring to FIG. 1, a fluid system 10 including a mixing block 100 and a fixture arrangement 200 including a fixture 300 are shown. The fluid system 10 includes a fluid source 12, the mixing block 100 and a fluid destination 14. The fluid source 12 is connected to the mixing block 100 and is configured to provide a flow of first fluid 2 and flow of a second fluid 4 to the mixing block 100. The mixing block 100 is connected to the fluid destination 14, is configured to intermix the first fluid 2 and the second fluid 4 and is further configured to provide a flow of an intermixed fluids 6 including the first fluid 2 and the second fluid 4 to the fluid destination 14. In this respect it is contemplated that the mixing block 100 include two or more inlet ports fluidly coupled to an outlet port by source channels and a mixing or supply channel; e.g., a first inlet port 102 (shown in FIG. 2) and a second inlet port 104 (shown in FIG. 2) fluidly coupled to an outlet port 106 (shown in FIG. 2) by a mixing channel 108 (shown in FIG. 2) and a first source channel 110 (shown in FIG. 2) as well as a second source channel 112 (shown in FIG. 2) defined within the mixing block 100; to provide the intermixed fluid 6 to the fluid destination 14.

The fixture arrangement 200 is configured to purge the mixing block 100 and in this respect includes the fixture 300, a first purge fluid source 202, a second purge fluid source 204, a first purge fluid conduit 206 and a second purge fluid conduit 208. The fixture 300 is configured to support the mixing block 100 during purging using a first purge fluid 210 and a second purge fluid 212, for example in a reverse flow arrangement wherein purge fluid issues from the first inlet port 102 (shown in FIG. 2) and the one or more second inlet port 104 (shown in FIG. 2) into an external environment 8 bounding a mixing block body 114 (shown in FIG. 2) included in the mixing block 100. It is contemplated that fixture 300 also be configured to effect reverse by introducing the purge fluid into either (or both) a first end face 118 (shown in FIG. 2) and a second end face 120 (shown in FIG. 2) of the mixing block body 114 to reverse flow the purge fluid through the first source channel 110 (shown in FIG. 2) and the one or more second source channel 112 (shown in FIG. 2). Advantageously, this enables employing pressure of gaseous purge fluid (e.g., a gaseous purge fluid at standard atmospheric conditions) to remove foreign material (e.g., chips, cuttings, and/or abrasive grit) that may be resident within the first source channel 110 and/or the one or more second source channel 112 following fabrication and/or cleaning using a gaseous purge fluid and assess efficacy of the removal using a liquid purge fluid (e.g., a purge fluid that is a liquid at standard atmospheric conditions). It also enables assessing comparative resistance to fluid flow of surface conditions (e.g., surface texturing) within one of the first source channel 110 and the one or more second source channel 112 relative to the other of the first source channel 110 and the one or more second source channel 112 using the liquid purge fluid, such as in source channels having interior texturing configured to extend service life of the mixing block 100 between refurbishment and/or replacement events.

The first purge fluid source 202 is configured to flow the first purge fluid 210 to the mixing block 100 and in this respect may include the first purge fluid 210 and be connected to the fixture 300 by the first purge fluid conduit 206. The second purge fluid source 204 may be similar to the first purge fluid source 202 and additionally be configured to flow the second purge fluid 212 to the mixing block 100. In this respect it is contemplated that the second purge fluid source 204 may include the second purge fluid 212 and be connected to the fixture 300 by the second purge fluid conduit 208. In certain examples the first purge fluid 210 may include (e.g., consist of or consist essentially of) a gas. Examples of suitable gases include nitrogen (N₂) gas, high-purity nitrogen (HPN), and clean dry air (CDA). In accordance with certain examples, the second purge fluid 212 may include (e.g., consist of or consist essentially of) water, deionized water, an etchant, or a detergent. As will be appreciated by those of skill in the art in view of the present disclosure, other purge fluids may be employed and remain within the scope of the present disclosure.

With reference to FIG. 2, the fluid system 10 (e.g., a semiconductor processing system) is shown according to an example of the present disclosure. In the illustrated example the fluid source 12 includes a first process fluid source 18 and a second process fluid source 20. The first process fluid source 18 is configured to provide a flow of a first process fluid 22 to the fluid destination 14 and in this respect is coupled to the first inlet port 102 of the mixing block 100 (e.g., a reactor manifold) by a first source conduit 24. The second process fluid source 20 is similar to the first process fluid source 18 is additionally configured to provide a flow of a second process fluid 26 to the fluid destination 14 and is coupled to the one or more second inlet port 104 of the mixing block 100 by a second source conduit 28. The mixing block 100 is in turn configured to intermix the first process fluid 22 with the second process fluid 26 and provide a flow of an intermixed process fluid 30 to the fluid destination 14.

In the illustrated example the fluid destination 14 includes a chamber arrangement 32. The chamber arrangement 32 includes a chamber body 34, a distribution plate 36, a substrate support 38 and an exhaust source 40. The chamber body 34 is connected to the outlet port 106 of the mixing block 100 to receive a flow of the intermixed process fluid 30 from the mixing block 100. The distribution plate 36 is fixed within the chamber body 34 and divides an interior 42 of the chamber body 34 into a distribution plenum 44 and a process volume 46. The substrate support 38 is arranged within the interior 42 of the chamber body 34 and is configured to support the substrate 3 during deposition of the material layer 5 onto the substrate 3 using the intermixed process fluid 30 received from the mixing block 100. The exhaust source 40 is connected to the chamber body 34 and fluidly coupled to the process volume 46 to remove residual process fluid and/or reaction products 48 from the within the interior 42 of the chamber body 34, which the exhaust source 40 communicates to the external environment 8 fluid system 10, such as through an abatement device like a scrubber.

In certain examples, either (or both) the first process fluid 22 and the second process fluid 26 may include a precursor or a reactant for material layer deposition process, such as a material layer deposition technique employing a CVD or ALD technique to deposit a material layer 5 onto a substrate 3 supported on the substrate support 38. In accordance with certain examples, either (or both) the first process fluid 22 and the second process fluid 26 may include an etchant or a catalyst for an etching process, such as for removal of material from the substrate 3 using a dry etch technique. Although the chamber arrangement 32 is shown and described herein as having a downflow architecture, it is to be understood and appreciated that chamber arrangement having other architectures may also benefit from the present disclosure, such as chamber arrangements having crossflow architectures by way of non-limiting example.

The mixing block 100 is configured to intermix the first process fluid 22 and the second process fluid 26 received at the first inlet port 102 and the second inlet port 104, respectively, and issue the intermixed process fluid 30 from the outlet port 106 of the mixing block 100. In this respect it is contemplated that the mixing block 100 include a mixing block body 114 formed a mixing block material 116 and extending longitudinally between a first end face 118 and a second end face 120. The mixing block body 114 may further have a first lateral face 122 and one or more second lateral face 124. The first lateral face 122 and the one or more second lateral face 124 may be between the first end face 118 and the second end face 120 of the mixing block body 114. It is further contemplated that the mixing block body 114 further define a plurality of flow channels 126 lateral between the first lateral face 122 and the one or more second lateral face 124 (and/or between the first end face 118 and the second end face 120) for intermixing the fluids received at the first inlet port 102 and the one or more second inlet port 104 for issue through the outlet port 106. In this respect it is contemplated that the mixing block body 114 define the mixing channel 108, the first source channel 110, and one or more second source channel 112 extending through the mixing block material 116 forming the mixing block body 114. In certain examples the mixing block material 116 make include (or consist of or consist essentially of) a metallic material. Examples of suitable metallic materials include stainless steel material such as 316stainless and Hastelloy or an aluminum alloy like 6061 aluminum. In accordance with certain examples, the mixing block material 116 may include (or consist of or consist essentially of) a polymeric material, such as ultra-high-molecular weight polyethylene (UHMW), which can limit cost of the fluid system 10 by simplifying manufacture of the mixing block body 114.

The mixing channel 108 extends between the first end face 118 and the second end face 120 and defines a confluence 128 along its length. It is contemplated that first source channel 110 and the one or more second source channel 112 join the mixing channel 108 at the confluence 128, for example at a first source channel outlet 130 and one or more second source channel outlet 132. It is further contemplated that the mixing channel 108 fluidly couple the confluence 128, and thereby the first source channel 110 and the one or more second source channel to the outlet port 106 via the first source channel outlet 130 and the one or more second source channel outlet 132, to the outlet port 106. It is contemplated that the outlet port 106 be defined by the first end face 118 of the mixing block body 114, which may in turn be substantially parallel to the second end face 120. In certain examples the second end face 120 of the mixing block body 114 may further define cul-de-sac port 134. In such examples the cul-de-sac port 134 may be coupled to the confluence 128 by the mixing channel 108, the mixing channel 108 fluidly coupling the first end face 118 to the second end face 120 of the mixing block body 114 via the cul-de-sac port 134 and the outlet port 106, which may simplify fabrication of the mixing block body 114 by enabling fabrication of the mixing block body 114 using a subtractive manufacturing process like boring. In certain examples an end cap body 136 may be fluidly seated on the first end face 118 of the mixing block body 114. The end cap body 136 may define a cul-de-sac channel segment 138 therein fluidly coupled to the mixing channel 108 by the cul-de-sac port 134, the cul-de-sac channel segment 138 extending the mixing channel 108 beyond the first end face 118 to promote fluid mixing within the mixing channel 108.

The first source channel 110 extends between the first inlet port 102 and the confluence 128 and fluidly couples the first inlet port 102 to the confluence 128 and therethrough to the outlet port 106 via the mixing channel 108. It is contemplated that the first inlet port 102 be defined by the first lateral face 122 of the mixing block body 114, and that the first lateral face 122 may be substantially planar in contour to promote fluid-tight sealing of the first source conduit 24 onto the mixing block body 114. In this respect the first lateral face 122 may be substantially orthogonal relative to either (or both) the first end face 118 and the second end face 120. In further respect, the first source channel 110 may have an inlet segment 140 and an outlet segment 142, the inlet segment 140 extending between the first inlet port 102 and the outlet segment 142 of the first source channel 110 and being substantially orthogonal relative to one or more of the first lateral face 122 and/or the mixing channel 108, the outlet segment 142 of the first source channel 110 coupling the inlet segment 140 of the first source channel 110 to the confluence and being oblique relative to one or more of the first lateral face 122 and the mixing channel 108. It is contemplated that one or more second source channel 112 be similar to the first source channel 110, additionally fluidly couple the one or more second inlet port 104 to the confluence 128, and that the one or more second lateral face 124 define the one or more second inlet port 104 and be substantially parallel to the first lateral face 122 and offset from the first lateral face 122 about a compression axis 144 defined by the mixing channel 108, which may simplify manufacture of the mixing block body 114. In the illustrated example the one or more second lateral face 124 is offset about the compression axis 144 by about 180 degrees relative to the first lateral face 122. As will be appreciated by those of skill in the art in view of the present disclosure, the one or more second lateral face 124 may be offset from the first lateral face 122 by less than 180 degrees or more than 180 degrees in other examples and remain within the scope of the present disclosure.

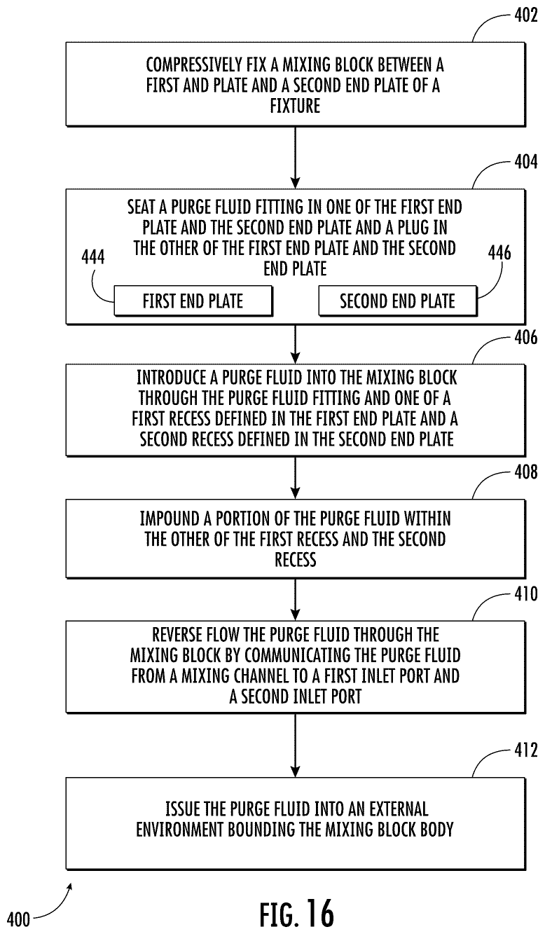

When the mixing block 100 is installed into the fluid system 10 illustrated in FIG. 2, mixing is accomplished by introducing the first process fluid 22 into the first inlet port 102 and the one or more second process fluid 26 into the one or more second inlet port 104. It is contemplated that the first source channel 110 communicate the first process fluid 22 from the first inlet port 102 to the confluence 128, and that the one or more second inlet port 104 communicate the one or more second process fluid 26 to from the one or more second inlet port 104 to the confluence 128. It is further contemplated that the mixing channel 108 intermix the first process fluid 22 and the one or more second process fluid 26 received at the confluence 128, and that the mixing channel 108 in turn communicate to the intermixed process fluids 30 and the one or more second fluid 4 to the fluid destination 14 (e.g., the chamber arrangement 32) via the outlet port 106. In the illustrated example the confluence 128 is proximal (e.g., relatively close) the first end face 118 and distal the second end face 120 of the mixing block body 114. As will be appreciated by those of skill in the art in view of the present disclosure, this can simplify fabrication of the mixing block body 114, for example by enabling formation of the inlet segment 140 using a subtractive manufacturing process like drilling and avoiding the porosity and surface roughness challenges that may exist in other techniques, such as additive manufacturing techniques like powder bed fusion. As will also be appreciated by those of skill in the art in view of the present disclosure, such subtractive techniques may require flushing of the mixing block body 114 to remove chips and debris from the plurality of flow channels 126 defined within the mixing block body 114, for example at the junction of the inlet segment 140 and the outlet segment 142. To facilitate such purging (or flushing), a fixture 300, the fixture arrangement 200, and a method 400 (shown in FIG. 16) of making a mixing block (e.g., the mixing block 100) are provided.

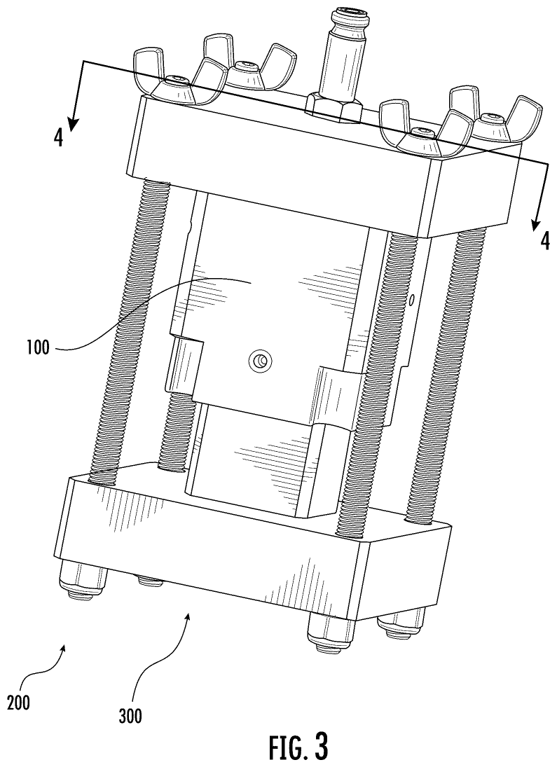

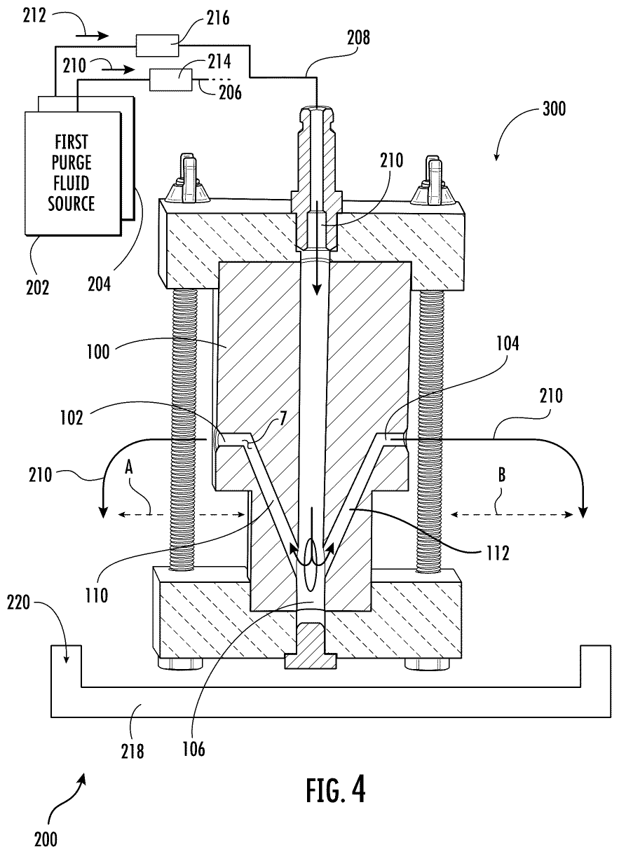

With reference to FIGS. 3 and 4, the fixture arrangement 200 is shown. The fixture arrangement 200 generally includes the mixing block 100 and the fixture 300. In the illustrated example the fixture arrangement 200 further includes a first flow control device 214, a second flow control device 216 and a basin 218. Although shown and described herein as having certain elements and a specific arrangement it is to be understood and appreciated that the fixture arrangement 200 may include additional elements and/or exclude certain elements shown and described herein, and/or have a different arrangement than shown and described herein, and remain within the scope of the present disclosure.

The fixture 300 is configured to support the mixing block 100 during purging and is this respect is configured to fluidly couple a purge source, e.g., the first purge fluid source 202 and/or the second purge fluid source 204, the mixing block 100. In certain examples the fixture 300 may support the mixing block 100 during reverse flow of a purge fluid, e.g., one or more of a first purge fluid 210 received from the first purge fluid source 202 and a second purge fluid 212 received from the second purge fluid source 204, through the mixing block 100. In this respect the fixture 300 may support the mixing block 100 such that the outlet port 106 is above the first inlet port 102 and the one or more second inlet port 104 relative to gravity. In accordance with certain examples, the fixture 300 may support the mixing block 100 in a different orientation, for example in an ordinary flow orientation wherein the outlet port 106 is in its orientation subsequent to installation 16 (shown in FIG. 1) into the fluid system 10 (shown in FIG. 1), i.e., such that the outlet port 106 is below the first inlet port 102 and the one or more second inlet port 104 relative to gravity. Advantageously, supporting the mixing block 100 in an orientation for reverse flow promotes even distribution of liquid purge fluid, e.g., one or more of the first purge fluid 210 and the second purge fluid 212, between the first source channel 110 and the one or more second source channel 112. As will also be appreciated by those of skill in the art in view of the present disclosure, support the mixing block 100 in a reverse flow orientation wherein purge fluid exits the mixing block body 114 from the first inlet port 102 and the one or more second inlet port 104 may also provide visual indication of whether one of the first source channel 110 and the one or more second source channel 112 is constricted relative to another of the first source channel 110 and the one or more second source channel 112, flow example due to comparative arcs of liquid purge flows issued from the mixing block body 114 and/or comparative distances of liquid purge fluid flows issued from the mixing block body 114.

The first purge fluid source 202 is configured to provide a flow of the first purge fluid 210 to the fixture 300 and therethrough to the mixing block 100. In this respect it is contemplated that the first purge fluid source 202 include the first purge fluid 210 and be coupled to the fixture 300 by the first purge fluid conduit 206. In certain examples the first purge fluid source 202 may be coupled to the first purge fluid conduit 206 by the first flow control device 214 which may in turn include one or more of an aperture plate, a restrictor, a metering valve, a pressure regulator, and pressure sensor. In accordance with certain examples, the first purge fluid 210 may include (or consist of or consist essentially of) a gaseous purge fluid. In this respect it is contemplated that that the first purge fluid 210 may include nitrogen (N₂) gas, oil-free air (OFA), clean dry air (CDA) or a mixture including one or more of the aforementioned gases. As will also be appreciated by those of skill in the art in view of the present disclosure, purging the mixing block body 114 with gases such as nitrogen (N₂) gas, OFA, and/or CDA may enable removal of foreign material from within the mixing block (e.g., solids like chips and/or cuttings as well as abrasive material used to impart a roughed surface texture to flow passages defined within the mixing block 100), while preserving cleanliness of the mixing block 100 and presenting relatively little risk contaminating the mixing block 100 with trace metals.

The second purge fluid source 204 is similar to the first purge fluid source 202 and is additionally configured to provide a flow of a second purge fluid 212 to the fixture 300 and therethrough to the mixing block 100. In this respect it is contemplated that the second purge fluid source 204 be coupled to the fixture 300 by the second purge fluid conduit 208. In certain examples the second purge fluid source 204 may be coupled to the second purge fluid conduit 208 by the second flow control device 216 which may in turn include one or more of an aperture plate, a restrictor, a metering valve, a pressure regulator, and pressure sensor. In certain examples, the second purge fluid 212 may include (or consist of or consist essentially of) a liquid purge fluid. Examples of suitable liquids include water, such as ultra-pure water (UPW) and deionized water. As will also be appreciated by those of skill in the art in view of the present disclosure, purging the mixing block 100 with liquids like UPW and deionized water can remove foreign material from within the mixing block resistant to removal by gas, such as detergent and/or residual etchants as well as etchant products, while preserving cleanliness of the mixing block 100 and presenting little associated risk of trace metal contamination.

The basin 218 may be positioned below the fixture 300 and configured to catch liquid purge fluid, e.g., the second purge fluid 212, issued from the mixing block 100. In certain examples the basin 218 may be configured with a rim 220 provide visual indication of flow resistance posed to the purge fluid by the first source channel 110 and the one or more second source channel 112. For example, fluid issuing from the mixing block 100 by less than a predetermined distance A may indicate occlusion of a flow channel, such as by a chip or cutting 7 resident within the first source channel 110. Alternatively (or additionally), fluid issuing from the mixing block 100 by more than the predetermined distance B may indicate an anomaly in surface texture, such as presence of residual patina on an interior surface of the one or more second source channel 112. As will be appreciated by those of skill in the art in view of the present disclosure, this can limit cost of the mixing block 100 and/or reliability of the fluid system 10 (shown in FIG. 1), for example by triggering rework of the mixing block 100 when foreign material is resident in a new-build mixing block as well as whether cleaning of refurbished mixing block has been successful.

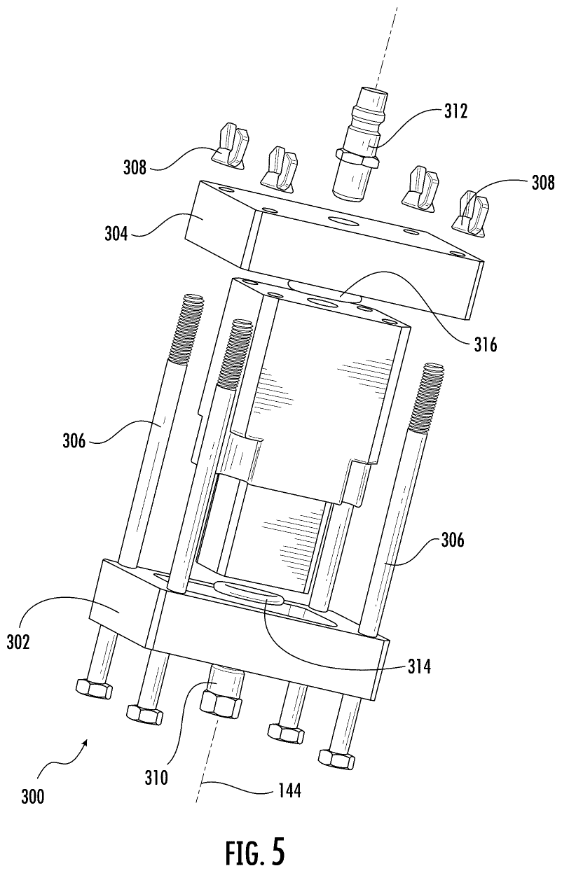

With reference to FIGS. 5-15, the fixture 300 is shown. Referring to FIG. 5, the fixture 300 may generally include a first end plate 302, a second end plate 304 and a plurality of threaded members 306. The fixture 300 may also include a plurality of compression members 308, a plug 310 and a purge fluid fitting 312. It is also contemplated that the fixture 300 may further include one or more seal member, for example a first seal member 314 and a second seal member 316. Although shown and described herein as having certain elements and arrangement, it is to be understood and appreciated that the fixture 300 may include additional elements and/or exclude elements shown and described herein, as well as have a different arrangement than that shown and described herein, and remain within the scope of the present disclosure. For example, as shown and described herein the fixture 300 includes four (4) threaded members 306 and four (4) compression members 308. This is for example and illustration purposes only and is non-limiting. As will be appreciated by those of skill in the art in view of the present disclosure, the fixture 300 may include fewer or additional threaded members and/or compression members and remain within the scope of the present disclosure. As will also be appreciated by those of skill in the art in view of the present disclosure, the fixture 300 include fewer or additional seal members and remain within the scope of the present disclosure.

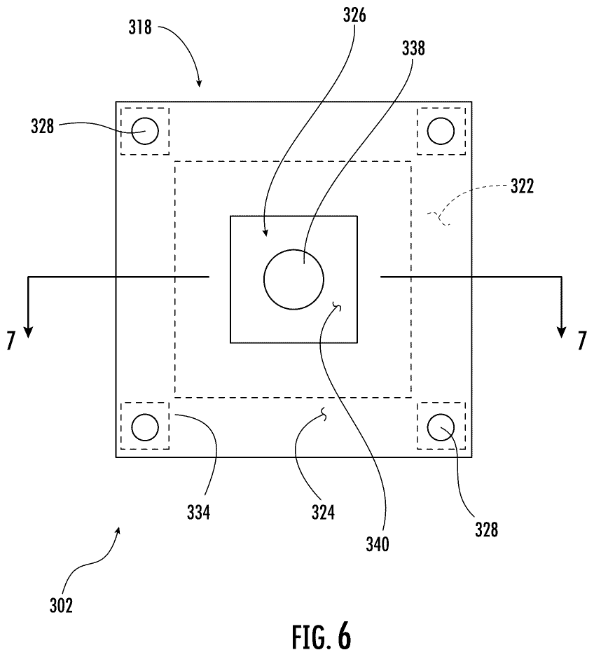

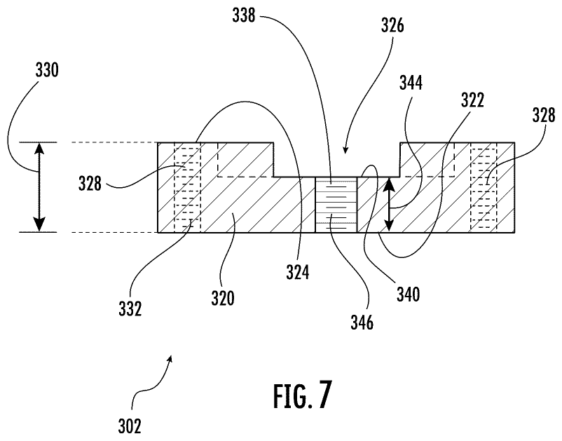

Referring to FIGS. 6 and 7, the first end plate 302 is shown. The first end plate 302 is configured to compressively fix the mixing block 100 (shown in FIG. 1) between the first end plate 302 and the second end plate 304 (shown in FIG. 5). In this respect it is contemplated that the first end plate 302 include a first end plate body 318 formed from a first end plate material 320 (shown in FIG. 4) and have a distal surface 322, a proximal surface 324, and a first end plate recess 326. The first end plate material 320 may have a hardness that is less than a hardness of the mixing block material 116 (shown in FIG. 2) forming the mixing block body 114 (shown in FIG. 2) In certain examples, the first end plate material 320 may include a metallic material such as stainless steel or an aluminum alloy. In accordance with certain examples, the first end plate material 320 may include (or consist of or consist essentially of) a polymeric material. Examples of suitable polymeric materials include UHMW, high density polyethylene (HDPE), and polyamide materials. As will be appreciated by those of skill in the art in view of the present disclosure, forming the first end plate 302 from a material having hardness that less a hardness of the mixing block material 116 forming the mixing block body 114 may limit risk of damage to the mixing block 100 during assembly of the fixture arrangement 200 (shown in FIG. 1), for example due to mishandling by bumping one of the sealing surfaces of the mixing block 100; e.g., the first end face 118 (shown in FIG. 2), the second end face 120 (shown in FIG. 2), the first lateral face 122 (shown in FIG. 2), and/or the one or more second lateral face 124 (shown in FIG. 2); during assembly of the fixture arrangement 200.

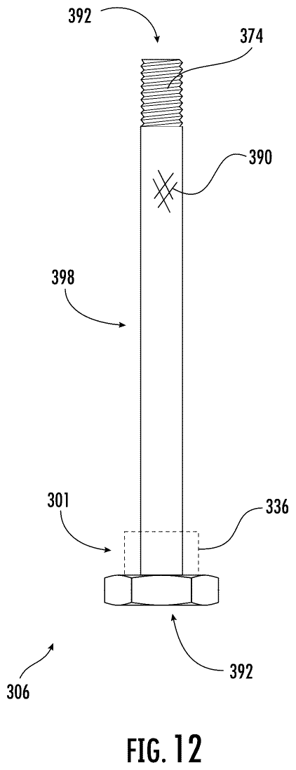

The distal surface 322 of the first end plate body 318 may define a plurality of threaded member apertures 328. The plurality of threaded member apertures 328 may individually be configured to receive therein a respective one of the plurality of threaded members 306 (shown in FIG. 5) and in this respect may extend through a major thickness 330 of the first end plate body 318 and be distributed about the first end plate recess 326. In certain examples, one or more of the plurality of threaded member apertures 328 may define therein a female threaded segment 332. In such examples the female threaded segment may correspond to a male threaded segment defined at least partially along the plurality of threaded members 306. In accordance with certain examples, the female threaded segment 332 may extend continuously and without interruption between the distal surface 322 and the proximal surface 324 of the first end plate body 318. It is also contemplated that, in accordance with certain examples, the plurality of threaded member apertures 328 may define an unthreaded substantially polygonal shape 334, such as a square or keyed shape. The polygonal shape 334 may correspond to a polygonal profile 336 (shown in FIG. 12) defined by one or more of the plurality of threaded members 306. As will be appreciated by those of skill in the art in view of the present disclosure, the polygonal shape 334 may cooperate with the polygonal profile 336 defined by the threaded member 306 to simplify assembly of the fixture arrangement 200 (shown in FIG. 1), for example by enabling assembly of the plurality of threaded members 306 into the first end plate 302 without the employment of tool by fixing the threaded member in rotation relative the first end plate 302.

In certain examples the distal surface 322 of the first end plate body 318 may define a plug/purge fluid fitting aperture 338. The plug/purge fluid fitting aperture 338 may couple the distal surface 322 of the first end plate body 318 to a first end plate recess surface 340 bounding the first end plate recess 326 of the first end plate body 318. It is contemplated that the plug/purge fluid fitting aperture 338 may be configured to seat therein the plug 310 (shown in FIG. 5) or the purge fluid fitting 312 (shown in FIG. 5). In this respect it is contemplated that the plug 310 and purge fluid fitting 312 may be interchangeable with one another, making the fixture 300 reversible. For example, the plug 310 may be seated in the second end plate 304 for purging the mixing block 100 (shown in FIG. 1) for purging with a gaseous purge fluid introduced into the mixing block body 114 (shown in FIG. 2) through the cul-de-sac port 134 (shown in FIG. 2), e.g., the first purge fluid 210 (shown in FIG. 1), and the plug 310 thereafter removed and subsequently seated in the first end plate 302, and the mixing block 100 purge with a liquid purge fluid, e.g., the second purge fluid 212 (shown in FIG. 1), introduced through the outlet port 106 (shown in FIG. 2).

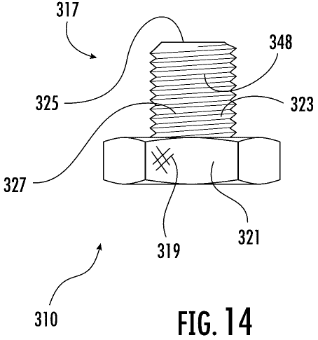

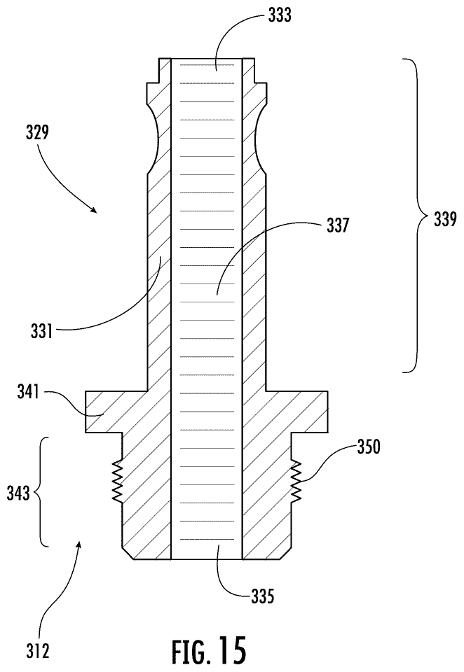

In certain examples, the plug/purge fluid fitting aperture 338 may define therein a female threaded segment 346. The female threaded segment 346 may correspond to one or more of a male threaded segment 348 (shown in FIG. 14) of the plug 310 (shown in FIG. 5) and a male threaded segment 350 (shown in FIG. 15) of the purge fluid fitting 312 (shown in FIG. 5), the female threaded segment 346 thereby effecting the above-describe interchangeability of the plug 310 the purge fluid fitting 312. In accordance with certain examples, the female threaded segment 346 of the plug/purge fluid fitting aperture 338 may only partially span a minor thickness 344 of the first end plate body 318. In this respect the female threaded segment 346 may extend from the distal surface 322 of the first end plate body 318 and terminate within the plug/purge fluid fitting aperture 338 at a location intermediate the distal surface 322 of the first end plate body 318 and the first end plate recess surface 340 of the first end plate body 318. As will be appreciated by those of skill in the art in view of the present disclosure, terminating the female threaded segment 346 at a location intermediate the distal surface 322 and the first end plate recess surface 340 of the first end plate body 318 may limit risk of the damage to the mixing block 100 (shown in FIG. 1) during assembly of the fixture arrangement 200 (shown in FIG. 1), by limiting (or eliminating) risk that the plug 310 (shown in FIG. 5) or the purge fluid fitting 312 (shown in FIG. 5) contact the first end face 118 (shown in FIG. 2) of the mixing block body 114 in the event an assembler overtightens the plug 310 or the purge fluid fitting 312 (and thereby excessively advances in a direction toward the first end face 118 to come into contact with a sealing surface defined thereon) during assembly of the fixture arrangement 200.

The first end plate recess 326 may be configured to receive therein a portion of the mixing block body 114 (shown in FIG. 2). In this respect it is contemplated that the first end plate recess 326 be sized to receive therein the first end face 118 (shown in FIG. 2) of the mixing block body 114. In further respect, the first end plate recess 326 may have a shape substantially matching an axial profile of the first end face 118 of the mixing block body 114. It is further contemplated that the plug/purge fluid fitting aperture 338 be defined within the first end plate recess surface 340 at location such that, when the first end face 118 of the mixing block body 114 is received in the first end plate recess aperture 342, the plug/purge fluid fitting aperture 338 is in registration with the cul-de-sac port 134 (shown in FIG. 2) of the mixing block body 114.

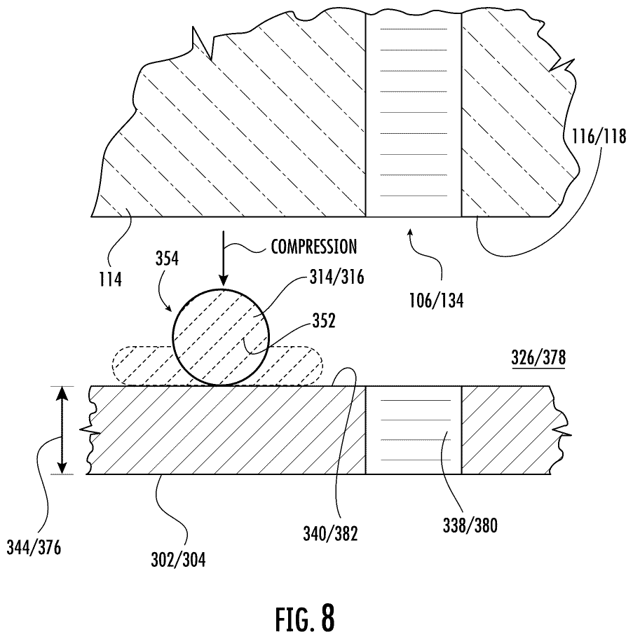

In certain examples, the major thickness 330 and the minor thickness 344 of the first end plate body 318 may be sized such that the first seal member 314 (shown in FIG. 5) may be interposed between the first end plate recess surface 340 of the first end face 118 of the mixing block body 114 (shown in FIG. 2) during assembly of the fixture arrangement 200 (shown in FIG. 1). In this respect it is contemplated that correspondence of the first end plate recess 326 to the first end face 118 of the mixing block body 114 may be such that the first end plate 302 may support the mixing block body 114 in substantially vertical position with the first seal member 314 in a substantially uncompressed condition (shown in FIG. 8) without requiring an assembler to hold the mixing block body 114 in a vertical orientation. As will be appreciated by those of skill in the art in view of the present disclosure, this can simplify assembly of the fixture arrangement 200, for example by enabling assembly of the fixture arrangement 200 by a single assembler by allowing the single assembler to register the second end plate 304 (shown in FIG. 5) to the second end face 120 (shown in FIG. 2) of the mixing block body 114 and thereafter slidably receive the plurality of threaded members 306 (shown in FIG. 5) in the second end plate 304.

As shown in FIG. 8, the first seal member 314 is shown according to an example of the present disclosure. It is contemplated that the first seal member 314 be formed from an elastomeric material 352, enabling compression of the mixing block body 114 between the first end plate 302 and the second end plate 304 (shown in FIG. 5) to fluidly seal the mixing block body 114 within the fixture 300 once assembled into the fixture arrangement 200. Examples of suitable elastomeric materials include fluorine rubbers such Viton®, available from The Chemours Company of Wilmington, Delaware (formerly E. I. du Pont de Nemours & Co.). It is also contemplated that the first seal member 314 may define a first seal member profile 354, which may be substantially circular when the first seal member 314 is a nominal condition, wherein the first seal member 314 may be uncompressed.

In certain examples, the first seal member 314 may be floated (e.g., movably supported) on the first end plate recess surface 340 in loose registration with the plug/purge fluid fitting aperture 338 during assembly of the fixture arrangement 200 (shown in FIG. 1). So supported, subsequent compression of first seal member 314 between the first end face 118 of the mixing block body 114 and the first end plate 302 may compressively fix the first seal member 314 between the first end plate recess surface 340 and the first end face 118 of the mixing block body 114. Compressive fixation of the first seal member 314 between the first end face 118 of mixing block body 114 and the first end plate recess surface 340 in turn fluidly couples the cul-de-sac port 134 of the mixing block body 114 to the plug/purge fluid fitting aperture 338. It is contemplated that the compressive fixation further fluidly seal the first end face 118 of the mixing block body 114 within the first end plate recess 326 in cooperation with the plug 310 (shown in FIG. 5), enabling purging of the mixing block body 114 by limiting fluid communication between the outlet port 106 and the external environment 8 (shown in FIG. 1) to the first inlet port 102 (shown in FIG. 2) and the one or more second inlet port 104 (shown in FIG. 2).

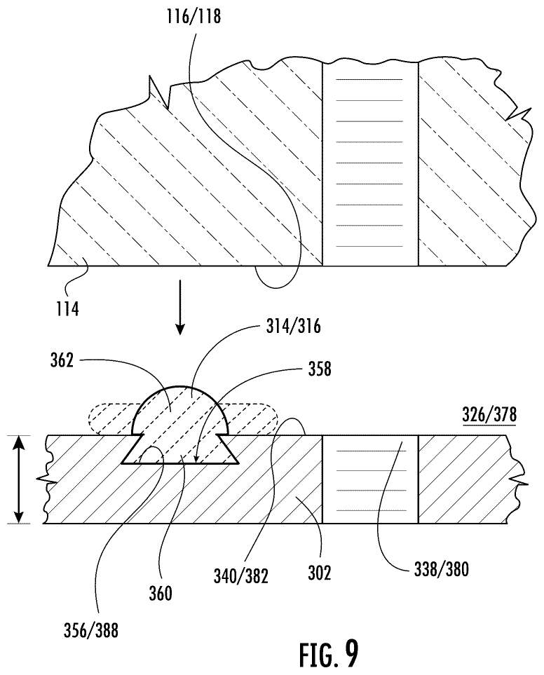

As shown in FIG. 9, the first end plate recess surface 340 may, in accordance with certain examples of the present disclosure, define a first seal member groove 356. The first seal member groove 356 may be configured to capture the first seal member 314 such that the first seal member 314 is carried by the first end plate 302 and fixed to the first end plate 302 prior to placement of the first end face 118 of the mixing block body 114 in the first end plate recess 326. The first seal member groove 356 may extend about the plug/purge fluid fitting aperture 338, for example circumferentially about the plug/purge fluid fitting aperture 338. In certain examples the first seal member groove 356 may define a necked or keystone profile 358, the necked or keystone profile 358 having a base 360 wider than an opening 362 of the necked or keystone profile 358. As will be appreciated by those of skill in the art in view of the present disclosure, compression of the first seal member 314 during insertion through the opening 362 and subsequent relaxation subsequent to insertion may fix the first seal member 314 within the first seal member groove 356. As will be appreciated by those of skill in the art in view of the present disclosure, this may simplify assembly and disassembly of the fixture arrangement 200 (shown in FIG. 2), for example by limiting the number of operations necessary to assemble the fixture arrangement 200, shortening the time required for assembly of the fixture arrangement 200 and cost associated with purging the mixing block body 114.

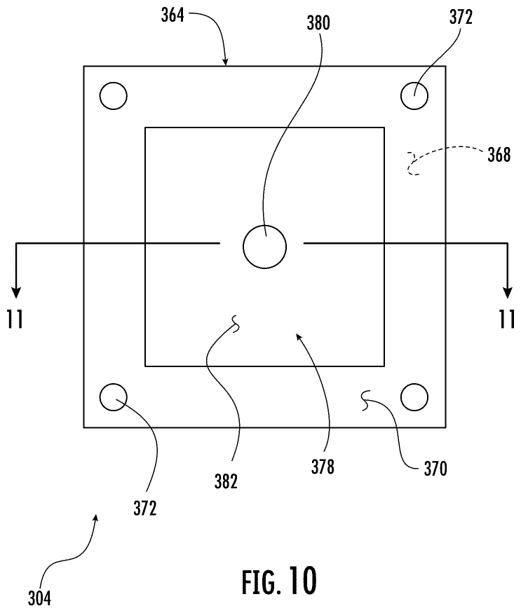

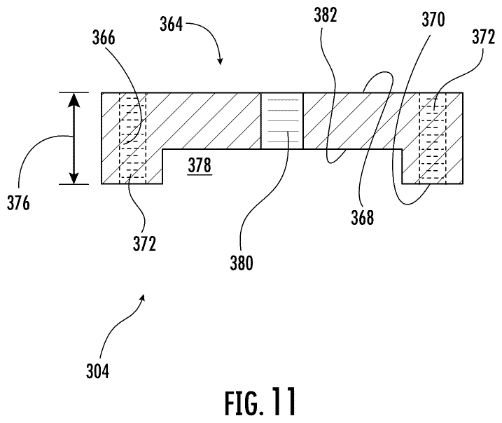

With reference to FIGS. 10 and 11, the second end plate 304 is shown. The second end plate 304 is similar to the first end plate 302 (shown in FIG. 5) and is configured to compress the mixing block 100 (shown in FIG. 2) against the first end plate 302. In this respect it is contemplated that the second end plate 304 include a second end plate body 364. The second end plate body 364 may be formed from a second end plate material 366 and have a distal surface 368 and a proximal surface 370. In certain examples, the second end plate material 366 may include (or consist of or consist essentially of) a metallic material. Examples of suitable metallic materials include stainless steel materials and aluminum alloy materials. In accordance with certain examples, the second end plate material 366 may include (or consist of or consist essentially of) a polymeric material. Examples of suitable polymeric materials include UHMW, HDPE and polyamide materials. It is contemplated that the second end plate material 366 forming the second end plate body 364 may have a hardness that is less than a hardness of the mixing block material 116 (shown in FIG. 2) forming the mixing block body 114 (shown in FIG. 2). Advantageously, forming the second end plate 304 from a material having hardness less than a hardness of the mixing block material 116 forming the mixing block body 114 may further limit risk of damage to the mixing block 100 during assembly of the fixture arrangement 200 (shown in FIG. 1), for example due to mishandling by bumping one of the sealing surfaces of the mixing block body 114 during assembly of the fixture arrangement 200.

It is contemplated that the distal surface 368 of the second end plate body 364 define a plurality of threaded member apertures 372. The plurality of threaded member apertures 372 may be configured to slidably receive therethrough the plurality of threaded members 306 (shown in FIG. 5). More specifically, it is contemplated that the plurality of threaded member apertures 372 be configured to receive therethrough male threaded segments 374 (shown in FIG. 12) of the plurality of threaded members 306, for example such that portions of the male threaded segments 374 of the plurality of threaded members 306 protrude from the distal surface 368 and in a direction opposite the first end plate 302 (shown in FIG. 5) and the mixing block body 114 (shown in FIG. 2). As will be appreciated by those of skill in the art in view of the present disclosure, this allows the compression members 308 (shown in FIG. 5) to be threadedly received on the plurality of threaded members 306 to compress the mixing block body 114 between the first end plate 302 and the second end plate 304. In this respect it is contemplated that the plurality of threaded member apertures 372 extend through a major thickness 376 of the second end plate body 364 and between the distal surface 368 and the proximal surface 370 of the second end plate body 364. In further respect, the plurality of threaded member apertures 372 may be distributed about a second end plate recess 378 defined in the proximal surface 370 of the second end plate 304 and configured to receive therein the second end face 120 (shown in FIG. 2) of the mixing block body 114. In certain examples, the plurality of threaded member apertures 372 may be substantially identical in shape as the plurality of threaded member apertures 328 (shown in FIG. 6) defined in the first end plate body 318 (shown in FIG. 6). As will appreciated by those of skill in the art in view of the present disclosure, this may make the second end plate 304 interchangeable with the first end plate 302 (shown in FIG. 3), simplifying assembly of the fixture arrangement 200 (shown in FIG. 1).

The second end plate recess 378 may be configured to receive therein the second end face 120 (shown in FIG. 2) of the mixing block body 114 (shown in FIG. 2) and communicate a purge fluid, e.g., the first purge fluid 210 (shown in FIG. 1) and/or the second purge fluid 212 (shown in FIG. 1), to mixing block body 114. In this respect it is contemplated that the second end plate recess 378 be substantially matched in dimension and shape with respect to the second end face 120 of the mixing block body 114. In further respect, it is also contemplated that the second end plate recess 378 define a plug/purge fluid fitting aperture 380. The plug/purge fluid fitting aperture 380 may extend between the distal surface 368 of the second end plate body 364 and a second end plate recess surface 382 bounding the second end plate recess 378. It is contemplated that the plug/purge fluid fitting aperture 380 may be configured to seat therein either of the plug 310 (shown in FIG. 5) and the purge fluid fitting 312 (shown in FIG. 5), the fixture 300 thereby configurable for purge fluid introduction both through the cul-de-sac port 134 (shown in FIG. 2) and the outlet port 106 (shown in FIG. 2) of the mixing block body 114. In certain examples the second end plate recess 378 may be substantially identical to the first end plate recess 326 (shown in FIG. 6) in one or more of shape, dimension and axial depth along the compression axis 144 (shown in FIG. 5) of the fixture 300. In accordance with certain examples, the second end plate recess 378 may be wider than the first end plate recess 326. As will be appreciated by those of skill in the art in view of the present disclosure, sizing the second end plate recess 378 to match one of the first end face 118 and the second end face 120 of the mixing block body 114 may can limit tendency of the mixing block body 114 to shift, e.g., such that the mixing channel 108 becomes skew relative to the compression axis 144, during compression of the mixing block body 114 between the second end plate 304 and the first end plate 302.

In certain examples the plug/purge fluid fitting aperture 338 may define therein a female threaded segment 384. The female threaded segment 384 may correspond to one or more of the male threaded segment 348 (shown in FIG. 14) of the plug 310 (shown in FIG. 5) and the male threaded segment 350 (shown in FIG. 15) of the purge fluid fitting 312 (shown in FIG. 5). The female threaded segment 384 may further span at least in part a minor thickness 386 of the second end plate body 364 defined between the second end plate recess surface 382 and the distal surface 368 of the second end plate body 364. In certain examples, the female threaded segment 384 defined with t the plug/purge fluid fitting aperture 380 may extend only partially through the minor thickness 386 of the second end plate body 364. In this respect it is contemplated that the female threaded segment 384 terminate at ax axial location intermediate the distal surface 368 of the second end plate body 364 and the second end plate recess surface 382 of the second end plate body 364. Advantageously, terminating the female threaded segment 384 at a location intermediate the distal surface 368 and the second end plate recess surface 382 may further limit risk of the damage to the mixing block 100 (shown in FIG. 1) during assembly of the fixture arrangement 200 (shown in FIG. 1), by limiting (or eliminating) risk that the plug 310 (shown in FIG. 3) or the purge fluid fitting 312 (shown in FIG. 3) contact the second end face 120 (shown in FIG. 3) of the mixing block 100, for example in the event that the plug 310 or the purge fluid fitting 312 is overtightened or advances in a direction toward the second end face 120 by magnitude sufficient to contact with a sealing surface defined on the mixing block body 114.

With continuing reference to FIGS. 8 and 9, the second seal member 316 is further shown. As shown in FIG. 8, the major thickness 376 and the minor thickness 386 of the second end plate body 364 may be sized such that the second seal member 316 may be interposed between the second end plate recess surface 382 of the second end face 120 of the mixing block body 114 during assembly of the fixture arrangement 200 (shown in FIG. 1). In this respect the second end plate recess 378 may correspond to the second end face 120 of the mixing block body 114 may be such that second seal member 316 may be supported on the second end face 120 of the mixing block body 114 at a location loosely registered to the outlet port 106, the second end plate 304 slidably received on the plurality of threaded members 306 (shown in FIG. 5), and the plurality of compression members 308 (shown in FIG. 5) thereafter threadedly seated the male threaded segment 374 (shown in FIG. 12) of the threaded members 306 and advanced such that the second seal member 316 is compressed between the second end plate recess surface 382 and the second end face 120 of the mixing block body 114. As will be appreciated by those of skill in the art in view of the present disclosure, loose registration of the second seal member 316 can simplify assembly of the fixture arrangement 200, for example by enabling assembly of the fixture arrangement 200 by a single assembler by avoiding the need of jig or adhesive to fix the second seal member 316 to the second end plate recess surface 382.

As shown in FIG. 9, the second end plate recess surface 382 may alternatively define a second seal member groove 388. The second seal member groove 388 may be similar to the first seal member groove 356 and additionally configured to capture the second seal member 316 in the second end plate recess 378. As above, capturing the second seal member 316 within the second end plate recess surface 382 may also simplify assembly of the fixture arrangement 200 (shown in FIG. 1) by further limiting the number of operations required to assemble the fixture arrangement 200.

With reference to FIG. 14, the threaded member 306 is shown. The threaded member 306 is configured to compressively fix the mixing block 100 (shown in FIG. 1) between the first end plate 302 (shown in FIG. 5) and the second end plate 304 (shown in FIG. 5) of the fixture 300 (shown in FIG. 1) and in this respect is formed from a threaded member material 390, has a head 392 and a longitudinally opposite tip 394, and defines the male threaded segment 374 intermediate the head 392 and the tip 394, which may be a blunt tip. The head 392 may be rounded or faceted and may be configured to receive thereon a tool to facilitate assembly of the threaded member 306 into the fixture 300. In certain examples the threaded member material 390 may include (e.g., consist of or consist essentially of) be a metallic material. Examples of suitable metallic materials include stainless steel materials, such as 316L stainless. In accordance with certain examples, the threaded member material 390 may include (or consist of or consist essentially of) a polymeric material. Examples of suitable polymeric materials include UHMW, HDPE and polyamide materials like nylon.

In certain examples, the threaded member material 390 may have a hardness that is less that a hardness of the mixing block material 116 (shown in FIG. 4) forming the mixing block body 114 (shown in FIG. 4). For example, the mixing block 100 may be formed from 316 stainless or Hastelloy, and the threaded member material 390 may have a hardness that is less than 316 stainless or Hastelloy. Advantageously, forming the plurality of threaded members 306 from a material with a material softer than that forming the mixing block body 114 may limit risk of damage to sealing surfaces defined on the mixing block body, e.g., the first lateral face 122 (shown in FIG. 2) and/or the one or more second lateral face 124 (shown in FIG. 2), during assembly of the fixture arrangement 200 (shown in FIG. 1).

The male threaded segment 374 of the threaded member 306 is configured the threadedly receive thereon the compression member 308 and in this respect extends from the tip 394 toward the head 392. The male threaded segment 374 may further protrude at least in part from the distal surface 368 (shown in FIG. 10) of the second end plate 304 (shown in FIG. 5) to threadedly receive thereon the compression member 308 (shown in FIG. 5) for compressive fixation of the mixing block body 114 (shown in FIG. 2) between the first end plate 302 (shown in FIG. 5) and the second end plate 304 (shown in FIG. 5). In certain examples, the male threaded segment 374 may extend continuously and without interruption from the tip 394 of the threaded member 306 to the head 392 of the threaded member 306. In accordance with certain examples, the male threaded segment 374 of the threaded member 306 may be separated from head 392 of the threaded member 306 by an unthreaded segment 398, such as an unthreaded segment 398 defining a substantially circular cross-sectional area. As will be appreciated by those of skill in the art in view of the present disclosure, examples include the unthreaded segment 398 may limit risk of damage to the sealing surfaces of the mixing block body 114, e.g., the first lateral face 122 (shown in FIG. 2) and/or the one or more second lateral face 124 (shown in FIG. 2), during assembly of the fixture arrangement 200 (shown in FIG. 1).

In certain examples the threaded member 306 may have a polygonal segment 301. The polygonal segment 301 may separate the head 392 from the male threaded segment 374 of the threaded member 306 and be proximate the head 392 of the threaded member 306. In such examples the polygonal segment 301 may conform with a polygonal shape defined by the threaded member aperture 328 (shown in FIG. 6) of the first end plate 302, the threaded member 306 in such examples being received within the threaded member aperture 328 in such examples such that the threaded member 306 is fixed in rotation relative to the first end plate 302 (shown in FIG. 3). Advantageously, fixing the threaded member 306 in rotation relative to the first end plate 302 may simplify assembly of the fixture arrangement 200 (shown in FIG. 1), for example by enable assembly of the threaded member 306 in the first end plate 302 without the use of a tool or fastener.

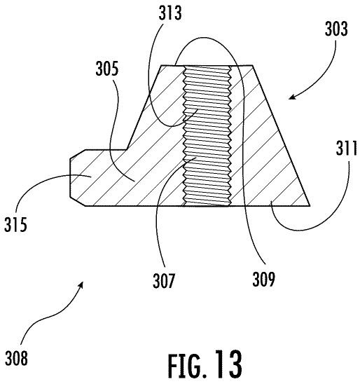

With reference to FIG. 13, the compression member 308 is shown. The compression member 308 is configured to urge the second end plate 304 (shown in FIG. 5) toward the first end plate 302 (shown in FIG. 5) in cooperation with the threaded member 306 (shown in FIG. 5), the mixing block body 114 (shown in FIG. 2) thereby being compressed between the first end plate 302 and the second end plate 304. In this respect it is contemplated that the compression member 308 include compression member body 303 formed from a compression member body material 305 and defining a compression member aperture 307. It is contemplated that the compression member aperture 307 extend longitudinally between a first end face 309 and a longitudinally opposite second end face 311 of the compression member body 303. It is further contemplated that the compression member aperture 307 define therein a female threaded segment 313. The female threaded segment 313 may extend longitudinally between the first end face 309 and the second end face 311 of the compression member body 303. The female threaded segment 313 may further include female threads corresponding to male threads defined on the male threaded segment 374 (shown in FIG. 12) of the threaded member 306 (shown in FIG. 5), the female threaded segment 313 thereby fixing the compression member 308 to the threaded member 306 on a side of the second end plate 304 opposite the mixing block body 114.

In certain examples, the compression member body material 305 may include a metallic material, such as stainless steel. It is also contemplated that the compression member body material 305 may include a polymeric material. Examples of suitable polymeric materials include UHMW, HDPE and polyamide materials. In accordance with certain examples, the compression member body 303 may have one or more lug 315 configured to enable an assembler to compressively fix the mixing block body 114 (shown in FIG. 2) between the first end plate 302 (shown in FIG. 5) and the second end plate 304 (shown in FIG. 5), for example without use of a tool. In such examples the one or more lug 315 may protrude laterally from the compression member body 303, for example laterally (at least in part) at a location longitudinally between the first end face 309 and the second end face 311 of the compression member body 303. As will be appreciated by those of skill in the art in view of the present disclosure, enabling assembly of the compression member 308 onto the threaded member 306 (shown in FIG. 5) without the use of a tool may simplify assembly of the fixture arrangement 200 (shown in FIG. 1).

With reference to FIG. 14, the plug 310 is shown. The plug 310 is configured to be threadedly received within either the plug/purge fluid fitting aperture 338 (shown in FIG. 6) defined by the first end plate 302 (shown in FIG. 5) and the plug/purge fluid fitting aperture 380 (shown in FIG. 10) defined by the second end plate 304 (shown in FIG. 5) to separate the first end plate recess 326 (shown in FIG. 6) or the second end plate recess 378 (shown in FIG. 10) from the external environment 8 (shown in FIG. 1), and in this respect includes a plug body 317. The plug body 317 is formed from a plug body material 319 and has a plug body head 321, a plug body stem 323 and a plug body face 325. The plug body material 319 may include a metallic material such as stainless steel or a polymeric material such as UHMW, HDPE and a polyamide material. The plug body head 321 and the plug body face 325 are located on longitudinally opposite ends of the plug body 317 and are separated from one another by the plug body stem 323. It is contemplated that that the plug body stem 323 include a male threaded segment 327. The male threaded segment 327 may define male threads corresponding to female threads of both the female threaded segment 332 (shown in FIG. 7) defined within the plug/purge fluid fitting aperture 338 and the female threaded segment 384 (shown in FIG. 11) defined within the plug/purge fluid fitting aperture 380 of the second end plate 304.

In certain examples, the plug 310 may be configured to sealably seat within either plug/purge fluid fitting aperture 338 (shown in FIG. 6) extending through the first end plate 302 (shown in FIG. 5) and the plug/purge fluid fitting aperture 380 (shown in FIG. 10) extending through the second end plate 304 (shown in FIG. 5), the fixture arrangement 200 (shown in FIG. 1) thereby being reversible. As will be appreciated by those of skill in the art in view of the present disclosure, respect sealably seating the plug 310 the plug/purge fluid fitting aperture 338 extending through the first end plate 302 enables flowing a gaseous purge fluid through the mixing block body 114 (shown in FIG. 2) in a reverse flow direction wherein purge fluid enters the mixing block body 114 through the cul-de-sac port 134 (shown in FIG. 4) and exits from the mixing block body from the first inlet port 102 (shown in FIG. 4) as well as the one or more second inlet port 104 (shown in FIG. 4). As will also be appreciated by those of skill in the art in view of the present disclosure, sealably seating the plug 310 the plug/purge fluid fitting aperture 380 of the first end plate 302 enables flowing a liquid purge fluid through the mixing block body 114 in a reverse flow direction wherein purge fluid enters the mixing block body 114 through the outlet port 106 (shown in FIG. 4) and also exits from the mixing block body from the first inlet port 102 (shown in FIG. 4) as well as the one or more second inlet port 104 (shown in FIG. 4). Advantageously, introducing gaseous purge fluid may improve the ability of the gaseous purge fluid to remove debris from the first source channel 110 (shown in FIG. 4) and the one or more second source channel 112 (shown in FIG. 4) in examples where the source channels join the mixing channel 108 at an acute angle proximate the first end face 118 (shown in FIG. 4) of the mixing block body 114 whereas introducing a liquid purge fluid into the mixing block body 114 through the outlet port 106 (shown in FIG. 4) may provide relatively even distribution of the liquid purge fluid in such examples where the source channels join the mixing channel 108 at an acute angle proximate the first end face 118 of the mixing block body 114.

In certain examples, the plug body stem 323 may have a length that is less than the minor thickness 344 (shown in FIG. 7) of the first end plate 302 (shown in FIG. 5) as well as the minor thickness 386 (shown in FIG. 11) of the second end plate 304 (shown in FIG. 5). Advantageously, this may limit risk of damage to sealing surfaces, e.g., the first end face 118 (shown in FIG. 2) and the second end face 120 (shown in FIG. 2), defined on the mixing block body 114 (shown in FIG. 1), for example by preventing an assembler from advancing the plug 310 to an extent that the plug body head 321 protrudes into the first end plate recess 326 (shown in FIG. 7) of the first end plate 302 or the second end plate recess 378 (shown in FIG. 11) of the second end plate 304, limiting (or eliminating) risk that the plug 310 damage the mixing block body 114 during assembly of the plug 310 into the fixture arrangement 200 (shown in FIG. 1) while retaining the advantageous reversibility described above.

With reference to FIG. 15, the purge fluid fitting 312 is shown. The purge fluid fitting 312 includes a purge fluid fitting body 329 formed from a purge fluid fitting material 331 and has an inlet 333 and an outlet 335. The inlet 333 is configured to receive a purge fluid from a purge source, e.g., the first purge fluid 210 (shown in FIG. 1) when coupled to the first purge fluid source 202 (shown in FIG. 1) and the second purge fluid 212 (shown in FIG. 1) when coupled to the second purge fluid source 204 (shown in FIG. 1), and is coupled to the outlet 335 by a purge fluid introduction channel 337. The purge fluid introduction channel 337 fluidly couples the inlet 333 of the purge fluid fitting body 329 to the outlet 335 of the purge fluid fitting body 329 and is configured to introduce the purge fluid into the fixture 300 (shown in FIG. 1), for example into either of the first end plate 302 (shown in FIG. 5) and the second end plate 304 (shown in FIG. 5) and therethrough into the mixing block body 114 (shown in FIG. 2).

The purge fluid fitting body 329 may have one or more of a stem segment 339, a flange 341 and a root segment 343. The root segment 343 may extend from the outlet 335 of the purge fluid fitting body 329 toward the flange 341 and define the male threaded segment 350. It is contemplated that male threads of the male threaded segment 350 of the purge fluid fitting body 329 may correspond to female threads defined within the first end plate 302 (shown in FIG. 5) and/or the second end plate 304 (shown in FIG. 5). For example, the male threads of the male threaded segment 350 may correspond to female threads of the female threaded segment 332 (shown in FIG. 7) defined within the plug/purge fluid fitting aperture 338 (shown in FIG. 6) of the first end plate 302 (shown in FIG. 5). The male threads of the male threaded segment 345 may correspond to female threads of the female threaded segment 384 defined within the plug/purge fluid fitting aperture 380 (shown in FIG. 11) of the second end plate 304 (shown in FIG. 5). It is also contemplated that the male threads of the male threaded segment 345 may correspond female threads of both the female threaded segment 332 defined within the first end plate 302 and female threads of the female threaded segment 384 defined within the second end plate 304. Advantageously, the aforementioned correspondence of the male threaded segment 345 with both the female threaded segment 332 and the female threaded segment 384 enables the purge fluid fitting 312 to be interchangeable with the plug 310 (shown in FIG. 5), enabling purging of the mixing block body 114 from both the first end face 118 (shown in FIG. 2) and the second end face 120 (shown in FIG. 2), as appropriate with the purge fluid employed for the purging.

The flange 341 of the purge fluid fitting body 329 is configured for seating a purge fluid fitting 312 onto either of the first end plate 302 (shown in FIG. 5) and the second end plate 304 (shown in FIG. 5), the flange 341 thereby enabling seating of the purge fluid fitting 312 in the first end plate 302 to flow the first purge fluid 210 (shown in FIG. 1) through the mixing block body 114 (shown in FIG. 2), enabling removal of the purge fluid fitting 312 from the first end plate 302 thereafter, and subsequently enabling seating of the purge fluid fitting 312 in the second end plate 304 to flow the second purge fluid 212 (shown in FIG. 1) through the mixing block body 114. In this respect the flange 341 may be intermediate (e.g., between) the root segment 343 and the stem segment 339 of the purge fluid fitting body 329 and extend circumferentially about the purge fluid introduction channel 337. In certain examples the flange 341 may be polygonal in shape, the polygonal shape in turn defining a plurality of facts distributed circumferentially about the purge fluid introduction channel 337, the flange 341 facilitating assembly of the fixture arrangement 200 (shown in FIG. 1) using a hand tool. In accordance with certain examples, the flange 341 may define one or more lug protruding laterally from the purge fluid fitting body 329, the flange 341 in such examples facilitating seating of the purge fluid fitting 312 is either of the first end plate 302 and the second end plate 304 without the use of a hand tool, simplifying assembly of the fixture arrangement 200.

The stem segment 339 of the purge fluid fitting body 329 is configured to seat thereon either of the first purge fluid conduit 206 (shown in FIG. 1) and the second purge fluid conduit 208 (shown in FIG. 1). In this respect the stem segment 339 may extend between the flange 341 and the inlet 333 of the purge fluid fitting body 329. In certain examples, the stem segment 339 may define a quick connect/disconnect feature 351. As will be appreciated by those of skill in the art in view of the present disclosure, such examples may simplify fabrication of the mixing block body 114 (shown in FIG. 2), for example by enabling switching between the first purge fluid source 202 (shown in FIG. 1) and the second purge fluid source 204 (shown in FIG. 1) without the use of a hand tool, for example in methods where the mixing block body 114 is purged (e.g., blown out) using a gaseous purge fluid and thereafter purge with a liquid purge fluid to remove additional debris and/or assess relative flow resistance within the first source channel 110 (shown in FIG. 2) and the one or more second source channel 112 (shown in FIG. 2).

In certain examples, the purge fluid fitting material 331 may include a metallic material, such as 316 stainless or Hastelloy. In accordance with certain examples, the purge fluid fitting material 331 may include a polymeric material such as UHMW, HDPE, or a polyamide material like nylon. It is also contemplated that the purge fluid fitting material 331 may have a hardness that is greater than that of the mixing block material 116 (shown in FIG. 2) in examples wherein first end plate 302 and second end plate 304 are configured to limit advancement of the purge fluid fitting 312 into the fixture arrangement 200 (shown in FIG. 1) to locations where the inlet 333 is intermediate the recess surface and the distal surface of the end plate, simplifying the fixture arrangement 200 by enabling the employment of a hydraulic quick coupling. For example, the purge fluid fitting 312 may include an ST Series hydraulic quick coupling, such as an SST 303 fitting, available from the Parker Hannifin Corporation of Mayfield Heights, Ohio.

With reference to FIGS. 1-18, a method 400 of making a mixing block, e.g., the mixing block 100 (shown in FIG. 1), is shown. As shown in FIG. 16, the method 400 includes compressively seating fixing a mixing block body of the mixing block between a first end plate and a second end plate of the fixture, e.g., the mixing block body 114 (shown in FIG. 2) between the first end plate 302 (shown in FIG. 3) and the second end plate 304 (shown in FIG. 3), as shown with box 402. The method 400 also includes seating a purge fluid fitting in one of the first end plate and the second end plate and a plug in the other of the first end plate and the second end late, e.g., the purge fluid fitting 312 (shown in FIG. 3) and the plug 310 (shown in FIG. 3), as shown with box 404. The method 400 further includes introducing a purge fluid into the mixing block body through one of first end plate recess defined in the first end plate and a second end plate recess defined in the second end plate, e.g., one of the first end plate recess 326 (shown in FIG. 6) and the second end plate recess 378 (shown in FIG. 10), as shown in box 406. It is contemplated that a portion of the purge fluid be impounded within the other of the first recess and the second recess, as shown in box 408. It is also contemplated that the purge fluid be reverse flowed through the mixing block body by communicating the purge fluid from a mixing channel, fluidly coupling the plug to the purge fluid fitting to a first inlet port and a second inlet port, e.g., from the mixing channel 108 (shown in FIG. 2) to the first inlet port 102 (shown in FIG. 2) and the second inlet port 104 (shown in FIG. 2), as shown in box 410. It is contemplated that the purge fluid introduced into the mixing block body issue from the first inlet port and the second outlet port into an external environment bounding the mixing block body, e.g., the external environment 8 (shown in FIG. 2), as shown with box 412.

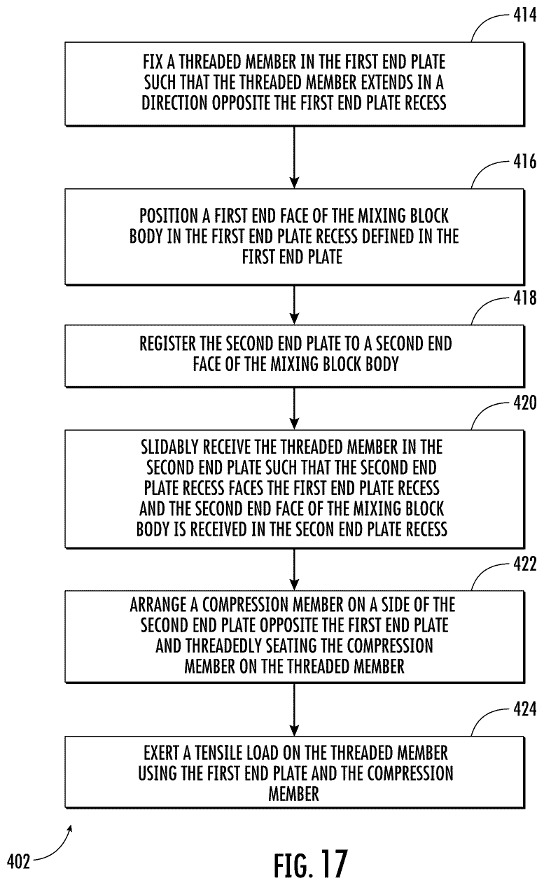

As shown in FIG. 17, compressively fixing 402 the mixing block body in the fixture may include fixing a threaded member within the first end plate, e.g., the first end plate 302 (shown in FIG. 5), as shown with box 414. Compressively fixing 402 the mixing block in the fixture may also include positioning a first end face of mixing block body in the first end face recess of the first end plate, e.g., the first end face 118 (shown in FIG. 2), as shown with box 416. Compressively fixing 402 the mixing block in the fixture may further include registering the second end plate to a second end face of the mixing block body, e.g., the second end face 120 (shown in FIG. 2) of the mixing block body, as shown with box 418. So registered, the threaded member may be slidably received in the second end plate with the second end plate recess facing the second end face of the mixing block body such that the second end face of the mixing block body is received in the second end plate recess of the second end plate and a male threaded segment of the threaded member protrudes from the second end plate is a direction opposite the second end plate recess, e.g., the male threaded segment 374 (shown in FIG. 12), as shown with box 420. It is contemplated that a compression member be arranged on a side of the second end plate opposite the first end plate and threadedly seated on the male threaded segment of the threaded member, as shown with box 422, and that the compression member and the first end plate cooperate to exert a tensile load on the threaded member as shown with box 424.

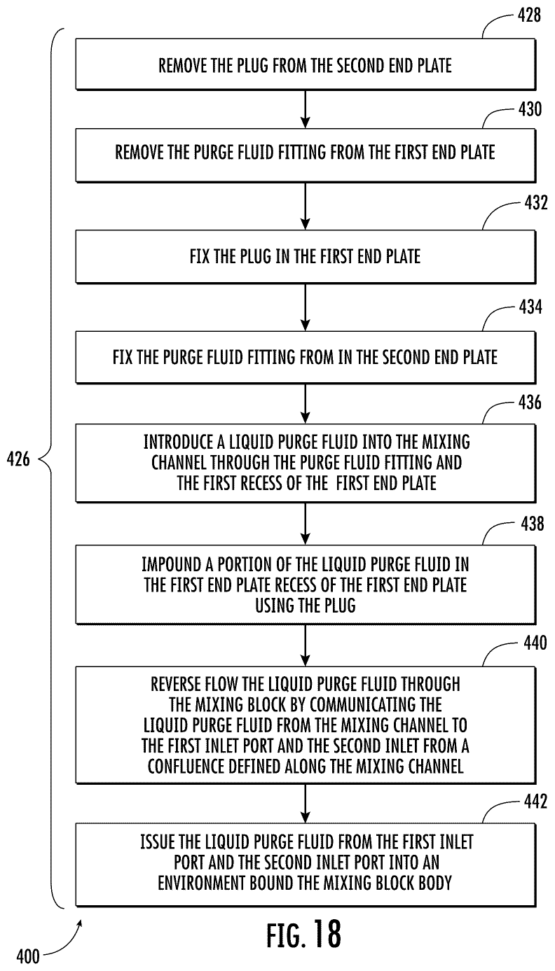

As shown in FIG. 18, the method 400 may further include reverse direction of purge fluid flow through the mixing channel of the mixing block body while retaining reverse flow of the purge fluid through a first source channel and a second channel of the mixing block body, e.g., the first source channel 110 (shown in FIG. 2) and the second source channel 112 (shown in FIG. 2), as shown with bracket 426. In this respect the purge fluid fitting may be removed from the first end plate and the plug removed from the second end plate, as shown with box 428 and box 430. The purge fluid fitting may be seated in the second end plate and the plug seated in the first end plate, the purge fluid fitting thereby fluidly coupled to the mixing channel by the second end plate recess and therethrough with the plug via the first end plate recess of the first end plate, as shown with box 432 and box 434. A purge fluid may then be introduced into the mixing channel of the mixing block body, for example through the second end face of the mixing block body, via the purge fluid fitting and the second end plate recess, as shown with box 436. It is contemplated that a portion of the purge fluid be impounded within the mixing block body between the plug and first end plate recess using the plug, the purge fluid thereby reverse flowing through the mixing block through the first source channel and the second source channel, as shown with box 438 and box 438, and that the purge fluid issue from the mixing block body (e.g., coincidently) from the first inlet port and the second inlet port and into the external environment bounding the mixing block body, as show with box 442.

With continuing reference to FIG. 16, a liquid purge fluid, e.g., the second purge fluid 212 (shown in FIG. 1), may be introduced through the second end plate while the second end face of the mixing block body is received in the second end plate recess, as shown with box 444. In such examples a portion of the liquid purge fluid may be impounded within the fixture arrangement between the plug and the confluence while the first inlet port and the second inlet port are above the confluence relative to gravity, as also shown with box 444. Advantageously, this enables assessment of surface conditions within the first source channel and the second source channel in relative terms according arc (and lateral distance) of the liquid purge fluid from the first inlet port and the second inlet port, limiting risk that a refurbished mixing block escape a refurbishment process with incomplete removal of accreted material from one of the first source channel and the second source channel in relation to the other of the first and second source channel. In certain examples, the fixture arrangement may further include a drip pan arranged below the first end plate relative to gravity, and issue distance compared relative to a lip of the drip pan to asses efficacy of a prior operation to remove chips and cuttings (as well as deburring) from within the first source channel and the second source channel, such as during cleaning following fabrication of a new-build mixing block as further shown with box 444. Advantageously, the distance traveled by the liquid purge fluid may further provide indication of which of the first source channel and the second source channel requires rework, limiting the amount of rework required when the cleaning process employed in a new-build mixing block has been unsuccessful.

It is also contemplated that a gaseous purge fluid, e.g., the first purge fluid 210 (shown in FIG. 1), may be introduced through the first end plate while the first end face of the mixing block body is received in the first end plate recess, as shown with box 446. In such examples a portion of the gaseous purge fluid may be impounded within the fixture arrangement between the plug and the confluence while the first inlet port and the second inlet port are below the confluence relative to gravity, as also shown with box 446. Advantageously, this enables forcing debris such as chips of cuttings resident within the first source channel and/or the second source channel using pressure of the gaseous purge fluid, improving efficacy of the removal operation employed to remove such material in a new-build mixing block.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A fixture, comprising:
a first end plate with a first end plate recess;
a threaded member fixed in the first end plate in extending in a direction opposite the first end plate recess;
a second end plate with a second end plate recess slidably received on the threaded member, the second end plate recess facing the first end plate recess; and
a compression member arranged on a side of the second end plate opposite the first end plate and threadedly seated on a male threaded segment of the threaded member to reverse flow a purge fluid through a mixing block compressively fixed between the first end plate and the second end plate.

2. The fixture of claim 1, wherein the first end plate is formed from a polymeric material, wherein the second end plate is formed from the polymeric material.

3. The fixture of claim 1, wherein the threaded member is formed from a polymeric material, and wherein the compression member is formed from a metallic material.

4. The fixture of claim 1, further comprising:
a first seal member arranged in the first end plate recess;
a second seal member arranged in the second end plate recess;
wherein the first seal member fluidly couples the first end plate to the second seal member; and
wherein the second seal member fluidly couples the second end plate to the first seal member.

5. The fixture of claim 4, wherein the first seal member is loose fit in the first end plate recess defined by the first end plate, and wherein the second seal member is loose fit in the second end plate recess of the second end plate.

6. The fixture of claim 4, wherein the first seal member is captive within a first end plate recess surface of the first end plate, and wherein the second seal member is captive in a second end plate recess surface of the second end plate.

7. The fixture of claim 1, further comprising:
a purge fluid fitting seated in the first end plate and fluidly coupled by the first end plate to the second end plate recess; and
a first purge fluid source including a first purge fluid coupled to the purge fluid fitting and fluidly coupled therethrough to the second end plate recess.

8. The fixture of claim 7, wherein the first purge fluid is a gaseous purge fluid.

9. The fixture of claim 7, wherein the first purge fluid includes oil-free air or clean dry air.

10. The fixture of claim 7, further comprising a plug seated in the second end plate and fluidly separating the second end plate recess from an external environment outside the fixture.

11. The fixture of claim 1, further comprising:
a purge fluid fitting seated in the second end plate and fluidly coupled by the second end plate to the first end plate recess; and
a second purge fluid source including a second purge fluid coupled to the purge fluid fitting and fluidly coupled therethrough to the first end plate recess.

12. The fixture of claim 11, wherein the first purge fluid is a liquid purge fluid.

13. The fixture of claim 11, wherein the second purge fluid includes ultra-pure water or deionized water.

14. A fixture arrangement, comprising:
a fixture as recited in claim 1;
a mixing block including a mixing block body compressively fixed between the first end plate and the second end plate, the mixing block body having:
a first end face with a cul-de-sac port received in the first recess of the first end plate;
a second end face with an outlet port longitudinally opposite the first end face received in the second recess of the second end plate, the outlet port fluidly coupled to the cul-de-sac port defined of the first end face by a mixing channel extending through the mixing block body;
a first lateral face with a first inlet port separating the second end face from the first end face, the first inlet port fluidly coupled to the mixing channel at a confluence; and
a second lateral face with a second inlet port separating the second end face from the first end face, the second inlet port fluidly coupled to the mixing channel at the confluence;
a purge fluid fitting seated in one of the first end plate and the second end plate to communicate a purge fluid to the mixing channel; and
a plug seated in the other of the first end plate and the second end plate to force the purge fluid through the first inlet port and the second inlet port of the mixing block body.

15. The fixture arrangement of claim 14, further comprising:
a first purge fluid source including a gaseous purge fluid coupled to the purge fluid fitting;
a first seal member arranged within the first recess and fluidly coupling the first purge fluid source to the cul-de-sac port of the mixing block body; and
wherein the first inlet port and the second inlet port fluidly couple the first purge fluid source through the cul-de-sac port to an external environment bounding the mixing block body.

16. The fixture arrangement of claim 14, further comprising:
a second purge fluid source including a liquid purge fluid coupled to the purge fluid fitting;
a second seal member arranged within the second recess and fluidly coupling the second purge fluid source to the outlet port of the mixing block body; and
wherein the first inlet port and the second inlet port fluidly couple the second purge fluid source through the cul-de-sac port to an external environment bounding the mixing block body.

17. The fixture arrangement of claim 14, wherein the purge fluid fitting is seated in the first end plate, wherein the first end face of the mixing block body is received in the first end plate recess, and wherein the first end plate recess separates the purge fluid fitting from the first end face of the mixing block body.

18. The fixture arrangement of claim 14, wherein the purge fluid fitting is seated in the second end plate, wherein the second end face of the mixing block body is received in the second end plate recess, and wherein the second end plate recess separates the purge fluid fitting from the second end face of the mixing block body.

19. The fixture arrangement of claim 14, wherein the mixing block is formed from a mixing block material having a hardness, wherein the first end plate is formed from a first end plate material having hardness that is less than the hardness of the mixing block material, wherein the second end plate is formed from a second end plate material having hardness that is less than the hardness of the mixing block material, and wherein the threaded member is formed from a threaded member material having a hardness that is less than the hardness of the mixing block material.

20. A method of making a mixing block, comprising:
at a mixing block including a mixing block body with a first end face with a cul-de-sac port, a second end face with an outlet port, a first lateral face with first inlet port, and second lateral face with a second inlet port, the first inlet port and the second inlet port fluidly coupled to the outlet port by a mixing channel extending between the cul-de-sac port and the outlet port;
compressively fixing the mixing block body in a fixture between a first end plate having a first end plate recess and a second end plate having second recess by:
fixing a threaded member in the first end plate such that the threaded member extends in a direction opposite the first end plate recess;
slidably receiving the threaded member in the second end plate such that the second end plate recess faces the first end plate recess;
arranging a compression member on a side of the second end plate opposite the first end plate and threadedly seating the compression member on the threaded member;
seating a purge fluid fitting one of the first end plate and the second end plate and a plug in the other of the first end plate and the second end plate;
introducing a purge fluid into the mixing channel through the purge fluid fitting and one of the first recess and the second recess, the plug member impounding a portion of the purge fluid within one of the first end plate recess and the second end plate recess;
reverse flowing the purge fluid through the mixing block body by communicating the purge fluid from the mixing channel to the first inlet port and the second inlet from a confluence defined along the mixing channel, the confluence coupled to the first inlet port by a first source channel and to the second inlet port by a second source channel; and
issuing the purge fluid from the first inlet port and the second inlet port into an environment bounding the mixing block body.

21. The method of claim 20, wherein the purge fluid is a gaseous purge fluid and the one of the first end plate and the second end plate is the first end plate of the fixture, the method further comprising:
removing the plug from the second end plate and the purge fluid fitting from the first end plate;
fixing the plug in the first end plate and the purge fluid fitting in the second end plate;
introducing a liquid purge fluid into the mixing channel through the purge fluid fitting and the second end plate recess, the plug member impounding a portion of the liquid purge fluid in the first end plate recess;
reverse flowing the liquid purge fluid through the mixing block body by communicating the liquid purge fluid from the mixing channel to the first inlet port and the second inlet from a confluence defined along the mixing channel; and
issuing the liquid purge fluid from the first inlet port and the second inlet port into an environment bound the mixing block body.

22. A mixing block made using the method of claim 20.

23. A semiconductor processing system, comprising:
a first process fluid source and a second process fluid source;
a mixing block made using the method of claim 20, wherein the first process fluid source is connected to the first inlet port of the mixing block body, wherein the second process fluid source is connected to the second inlet port of the mixing block body;
a chamber arrangement coupled to the outlet port of the mixing block body and therethrough to the first process fluid source and the second process fluid source;
a substrate support and a distribution plate arranged within the chamber arrangement,
wherein the distribution plate fluidly couples the substrate support to the mixing block body a chamber arrangement to deposit a material layer onto a substrate and/or remove material from the substrate using a first process fluid from the first process fluid source and a second process fluid from the second process fluid source intermixed by the mixing block body.
